(19) United States
(12) Patent Application Publication
(10) Pub. No.: US 2025/0273482 A1
(43) Pub. Date: Aug. 28, 2025

(54) METHOD OF MANUFACTURING SEMICONDUCTOR PACKAGE

(71) Applicant: Samsung Electronics Co., Ltd., Suwon-si (KR)

(72) Inventors: Myoungchul Eum, Suwon-si (KR); Hansol Yoo, Suwon-si (KR); Subin Jo, Suwon-si (KR)

(21) Appl. No.: 19/019,578

(22) Filed: Jan. 14, 2025

(30) Foreign Application Priority Data
Jan. 15, 2024 (KR) 10-2024-0006301

(51) Int. Cl. H01L 21/56; H01L 21/48; H01L 21/683; H01L 23/00; H01L 23/552; H01L 25/065; H10B 80/00

(52) U.S. Cl. CPC H01L 21/566; H01L 21/4853; H01L 21/6836; H01L 23/552; H01L 24/48; H01L 25/0652; H01L 24/16; H01L 24/32; H01L 24/73; H01L 24/96; H01L 24/97; H01L 25/0655; H01L 2221/68381; H01L 2224/16227; H01L 2224/16238; H01L 2224/32145; H01L 2224/32225; H01L 2224/48147; H01L 2224/48227; H01L 2224/48228; H01L 2224/73204; H01L 2224/73215; H01L 2224/73265; H01L 2224/96; H01L 2224/97; H01L 2924/1815; H10B 80/00

(57) ABSTRACT

A method of manufacturing a plurality of semiconductor packages includes preparing a plurality of molding structures each including a package substrate, at least one semiconductor chip attached onto the package substrate, a molding layer covering the package substrate and surrounding the at least one semiconductor chip, a plurality of package connection terminals attached to a lower surface of the package substrate, a release layer conformally covering the lower surface of the package substrate and conformally covering surfaces of the plurality of package connection terminals, and an adhesive layer covering the release layer, attaching the plurality of molding structures onto a support structure, forming a preliminary electromagnetic shielding layer covering an upper surface and side surfaces of each of the plurality of molding structures, and forming the plurality of semiconductor packages by photodecomposing the release layer and separating the adhesive layer from each of the plurality of molding structures.

### CROSS-REFERENCE TO RELATED APPLICATION

This application is based on and claims priority under 35 U.S.C. § 119 to Korean Patent Application No. 10-2024-0006301, filed on Jan. 15, 2024, in the Korean Intellectual Property Office, the disclosure of which is incorporated by reference herein in its entirety.

### BACKGROUND

Aspects of the inventive concept relate to a method of manufacturing a semiconductor package, and more particularly, to a method of manufacturing a semiconductor package having an electromagnetic shielding layer.

In accordance with the rapid development of the electronics industry and the demand of users, electronic devices are becoming more high-performance and miniaturized, and thus, semiconductor packages including an electromagnetic shielding layer capable of shielding electro-magnetic interference (EMI) between components included in electronic devices have been developed.

### SUMMARY

Aspects of the inventive concept provide a method of manufacturing a semiconductor package capable of shielding electromagnetic waves.

According to an aspect of the inventive concept, a method of manufacturing a semiconductor package includes preparing a plurality of molding structures each comprising: a package substrate, at least one semiconductor chip attached onto the package substrate, a molding layer covering an upper surface of the package substrate and surrounding the at least one semiconductor chip, a plurality of package connection terminals attached to a lower surface of the package substrate, a release layer conformally covering the lower surface of the package substrate and conformally covering surfaces of the plurality of package connection terminals, and an adhesive layer covering the release layer and surrounding the plurality of package connection terminals; attaching the plurality of molding structures onto a support structure so as to be spaced apart from each other in a horizontal direction; forming, on the support structure, a preliminary electromagnetic shielding layer covering an upper surface of each of the plurality of molding structures and side surfaces of each of the plurality of molding structures; and forming a plurality of semiconductor packages by photodecomposing the release layer and separating the adhesive layer from each of the plurality of molding structures, wherein each semiconductor package of the plurality of semiconductor packages comprises: the corresponding package substrate, the corresponding at least one semiconductor chip, the corresponding molding layer, the corresponding plurality of package connection terminals, and an electromagnetic shielding layer that is a corresponding separated portion of the preliminary electromagnetic shielding layer that covers the upper surface and side surfaces of the semiconductor package.

According to another aspect of the inventive concept, a method of manufacturing a semiconductor package includes preparing a preliminary package substrate comprising a plurality of package regions; attaching at least one semiconductor chip onto the preliminary package substrate in each of the plurality of package regions; forming a preliminary molding layer covering an upper surface of the preliminary package substrate and surrounding the at least one semiconductor chip in each of the plurality of package regions; forming a package molding structure by attaching a plurality of package connection terminals to a lower surface of the preliminary package substrate in each of the plurality of package regions; forming a release layer by using a coating method to conformally cover the lower surface of the preliminary package substrate and to conformally cover surfaces of the plurality of package connection terminals; forming an adhesive layer covering the release layer and surrounding the plurality of package connection terminals; forming a plurality of molding structures by separating the package molding structure in which the release layer and the adhesive layer are formed such that the separated portions of the package molding structure correspond to each of the plurality of package regions, wherein each of the plurality of molding structures comprises: a package substrate that is a separated portion of the preliminary package substrate, the at least one semiconductor chip, a molding layer that is a separated portion of the preliminary molding layer, the plurality of package connection terminals, the release layer, and the adhesive layer; attaching the plurality of molding structures to a support structure; forming a preliminary electromagnetic shielding layer on the support structure to cover an upper surface of each of the plurality of molding structures and side surfaces of each of the plurality of molding structures; and forming a plurality of semiconductor packages by photodecomposing the release layer and separating the adhesive layer from each of the plurality of molding structures, wherein each semiconductor package of the plurality of semiconductor packages comprises: the corresponding package substrate, the corresponding at least one semiconductor chip, the corresponding molding layer, the corresponding plurality of package connection terminals, and an electromagnetic shielding layer that is a corresponding separated portion of the preliminary electromagnetic shielding layer that covers the upper surface and side surfaces of the semiconductor package.

According to another aspect of the inventive concept, a method of manufacturing a semiconductor package includes preparing a preliminary package substrate comprising a plurality of package regions; stacking a plurality of semiconductor chips in a step form on the preliminary package substrate in each of the plurality of package regions; forming a plurality of bonding wires to electrically connect the plurality of semiconductor chips to the preliminary package substrate; forming a preliminary molding layer covering an upper surface of the preliminary package substrate and surrounding the plurality of semiconductor chips and the plurality of bonding wires in each of the plurality of package regions; forming a package molding structure by attaching a plurality of package connection terminals to a lower surface of the preliminary package substrate in each of the plurality of package regions; forming a release layer comprising a material that is photodecomposable by laser or ultraviolet (UV) light by using a coating method to conformally cover the lower surface of the preliminary package substrate and to conformally cover surfaces of the plurality of package connection terminals; forming an adhesive layer to surround the plurality of package connection terminals, the adhesive layer covering the release layer, the adhesive layer having a thickness of a value greater than a height of the plurality of package connection terminals, and the adhesive layer comprising a thermosetting polymer or a photocurable polymer; forming a plurality of molding structures by separating the package molding structure in which the release layer and the adhesive layer are formed such that the separated portions of the package molding structure correspond to each of the plurality of package regions, wherein each of the plurality of molding structures comprises: a package substrate that is a separated portion of the preliminary package substrate, the plurality of semiconductor chips, a molding layer that is a separated portion of the preliminary molding layer, the plurality of package connection terminals, the release layer, and the adhesive layer; attaching the plurality of molding structures onto a support structure; forming a preliminary electromagnetic shielding layer on the support structure to cover an upper surface of each of the plurality of molding structures and side surfaces of each of the plurality of molding structures; and forming a plurality of semiconductor packages by photodecomposing the release layer and separating the adhesive layer from each of the plurality of molding structures, wherein each semiconductor package of the plurality of semiconductor packages comprises: the corresponding package substrate, the corresponding plurality of semiconductor chips, the corresponding molding layer, the corresponding plurality of package connection terminals, and an electromagnetic shielding layer that is a corresponding separated portion of the preliminary electromagnetic shielding layer that covers the upper surface and side surfaces of the semiconductor package.

### BRIEF DESCRIPTION OF THE DRAWINGS

Embodiments will be more clearly understood from the following detailed description taken in conjunction with the accompanying drawings in which:

FIG. 1 is a cross-sectional view showing a semiconductor package according to an embodiment;

FIGS. 2A to 2K are cross-sectional views showing a method of manufacturing a semiconductor package according to an embodiment;

FIG. 3 is a cross-sectional view showing a semiconductor package according to an embodiment;

FIGS. 4A to 4K are cross-sectional views showing a method of manufacturing a semiconductor package according to an embodiment;

FIG. 5 is a diagram showing a release layer used in a method of manufacturing a semiconductor package according to an embodiment;

FIGS. 6A to 6D are diagrams showing a release layer used in a method of manufacturing a semiconductor package according to an embodiment;

FIG. 7 is a diagram showing an adhesive layer used in a method of manufacturing a semiconductor package according to an embodiment; and

FIGS. 8A to 8D are diagrams showing an adhesive layer used in a method of manufacturing a semiconductor package according to an embodiment.

### DETAILED DESCRIPTION OF THE EMBODIMENTS

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

Spatially relative terms, such as “lower,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “lower” elements or features would then be oriented as “upper” elements or features. Thus, the term “lower” can encompass both an orientation of above and below. The device may be otherwise oriented (rotated 90 degrees or at other orientations) and the spatially relative descriptors used herein interpreted accordingly.

The various pads described herein may generally have a planar upper surface having horizontal dimensions (e.g., in both the X and Y directions) that are both larger than wiring to which the pad is connected to facilitate connections thereto (e.g., to provide a larger surface to contact with a later formed via). For example, a horizontal wiring may be integrally formed with a pad (e.g., patterned out of the same metal layer) such that the wiring and pad have coplanar upper surfaces, with both of the X and Y horizontal dimensions of the pad being greater than the horizontal width of the wiring (e.g., greater or equal to 3 times the horizontal width of the wiring). In other examples, a pad may be discretely formed such that it is not in contact with any wiring formed at its vertical level within the device and is only connected to wiring within the device by vias. From a top down view, a pad may have a symmetrical shape (e.g., a square or rectangular footprint) and may have X and Y horizontal dimensions that are about the same (e.g., within half to two times of the other).

The various layers described herein may each be a single homogenous layer (formed of the same base material throughout). For example, these patterns may each be formed with a single corresponding process (e.g., in situ-in a chamber without vacuum break to the chamber).

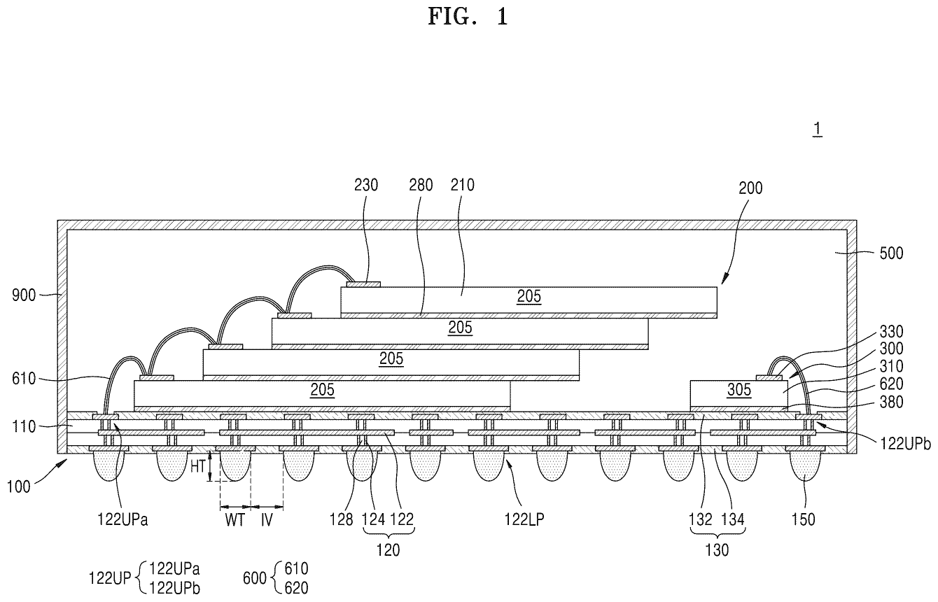

FIG. 1 is a cross-sectional view showing a semiconductor package 1 according to an embodiment.

Referring to FIG. 1, the semiconductor package 1 includes a package substrate 100, a plurality of first semiconductor chips 200, at least one second semiconductor chip 300, a molding layer 500, and an electromagnetic shielding layer 900. The plurality of first semiconductor chips 200 and the at least one second semiconductor chip 300 may be attached onto a package substrate 100. The molding layer 500 may surround the plurality of first semiconductor chips 200 and the at least one second semiconductor chip 300 on the package substrate 100. The electromagnetic shielding layer 900 may cover the package substrate 100 and the molding layer 500.

In some embodiments, the package substrate 100 may be a printed circuit board. For example, the package substrate 100 may be a double-sided printed circuit board or a multi-layer printed circuit board. The package substrate 100 may include at least one substrate base 110 and a substrate wiring structure 120.

The substrate base 110 may include at least one material selected from phenol resin, epoxy resin, and polyimide. For example, the substrate base 110 may include at least one material selected from Flame Retardant 4 (FR-4), tetrafunctional epoxy, polyphenylene ether, epoxy/polyphenylene oxide, bismaleimide triazine (BT), thermount, cyanate ester, polyimide, and liquid crystal polymer.

In some embodiments, the package substrate 100 may include a plurality of substrate bases 110 that are stacked. When the package substrate 100 includes the plurality of substrate bases 110 that are stacked, the plurality of substrate bases 110 may each include a core layer and at least one prepreg stacked on each of an upper surface and a lower surface of the core layer. In some embodiments, the core layer and the at least one prepreg layer may include the same material. A thickness of the at least one prepreg layer may be thinner than a thickness of the core layer.

In this specification, the at least one substrate base 110 or the plurality of substrate bases 110 means the entire substrate base 110 included in the package substrate 100, that is, one substrate base 110 when the package substrate 100 includes one substrate base, means a structure in which two or more substrate bases 110 are stacked when the package substrate 100 includes the two or more substrate bases 110 that are stacked, and means upper surfaces and lower surfaces of the at least one substrate base 110 or the plurality of substrate bases 110 mean upper surfaces and lower surfaces of the entire substrate base 110 included in the package substrate 100.

The substrate wiring structure 120 may include a plurality of substrate wiring patterns 122 disposed on the upper surface and the lower surface of the substrate base 110 or disposed inside the substrate base 110 and extending in a horizontal direction, and a plurality of substrate via patterns 124 penetrating at least a part of the at least one substrate base 110 and extending in a vertical direction so as to electrically connect two substrate wiring patterns 122 located at different vertical levels among the plurality of substrate wiring patterns 122. In some embodiments, the package substrate 100 may include the plurality of substrate bases 110 that are stacked, and the plurality of substrate wiring patterns 122 may be respectively disposed on the upper surfaces and the lower surfaces of the plurality of substrate bases 110. For example, some of the plurality of substrate wiring patterns 122 may be disposed between two substrate bases 110 adjacent in the vertical direction among the plurality of substrate bases 110.

The substrate wiring structure 120 may include copper (Cu) or an alloy including copper (Cu). Each of the plurality of substrate wiring patterns 122 may include electrolytically deposited (ED) copper foil, rolled-annealed (RA) copper foils, ultra-thin copper foil, sputtered copper, copper alloys, etc. Each of the plurality of substrate via patterns 124 may be formed to fill at least a part of a via through hole penetrating the substrate base 110. For example, the substrate via pattern 124 may include copper, nickel, stainless steel, or beryllium copper. In some embodiments, the substrate via pattern 124 may cover an inner wall of the via through hole penetrating the substrate base 110 and may not completely fill the via through hole, and a via filling insulating layer 128 may cover the substrate via pattern 124 and fill the via through hole. For example, the via through hole may be completely filled by the substrate via pattern 124 and the via filling insulating layer 128.

The package substrate 100 may further include a solder resist layer 130 covering the upper surface and the lower surface of the at least one substrate base 110. The solder resist layer 130 may include an upper solder resist layer 132 covering the upper surface of the at least one substrate base 110 and a lower solder resist layer 134 covering the lower surface of the at least one substrate base 110.

Some parts of the substrate wiring patterns 122 disposed on the upper surface of the at least one substrate base 110 may be a plurality of upper connection pads 122UP. For example, some parts of the uppermost substrate wiring patterns 122 located at the highest vertical level may be the plurality of upper connection pads 122UP. The upper solder resist layer 132 may cover side surfaces of the substrate wiring patterns 122 disposed on the upper surface of the at least one substrate base 110. Some parts of the substrate wiring patterns 122 disposed on the upper surface of the at least one substrate base 110 may not be completely covered by the upper solder resist layer 132. In some embodiments, the upper solder resist layer 132 may not cover at least a part of the upper surfaces of the plurality of upper connection pads 122UP. For example, the upper solder resist layer 132 may cover a part of the upper surface of each of the plurality of substrate wiring patterns 122 adjacent to side surfaces of each of the plurality of upper connection pads 122UP, but may not cover the remaining part of the upper surface (e.g., the middle portion of the upper surface). Among the substrate wiring patterns 122 disposed on the upper surface of the at least one substrate base 110, the substrate wiring patterns 122 of which at least a part of the upper surfaces are not covered by the upper surface solder resist layer 132 may be the plurality of upper connection pads 122UP. A plurality of bonding wires 600 may be connected to the plurality of upper connection pads 122UP. The plurality of bonding wires 600 may include a first bonding wire 610 and a second bonding wire 620. The plurality of upper connection pads 122UP may each include a first upper connection pad 122UPa and a second upper connection pad 122UPb. The first bonding wire 610 may be connected to the first upper connection pad 122UPa, and the second bonding wire 620 may be connected to the second upper connection pad 122UPb.

Some parts of the substrate wiring patterns 122 disposed on the lower surface of the at least one substrate base 110 may be a plurality of lower connection pads 122LP. For example, some parts of the lower substrate wiring patterns 122 located at the lowest vertical level may be the plurality of lower connection pads 122LP. The lower solder resist layer 134 may cover the side surfaces of the substrate wiring patterns 122 disposed on the lower surface of the at least one substrate base 110. Some parts of the substrate wiring patterns 122 disposed on the lower surface of the at least one substrate base 110 may not be completely covered by the lower solder resist layer 134. In some embodiments, the lower solder resist layer 134 may not cover at least a part of lower surfaces of the plurality of lower connection pads 122LP (e.g., middle portions of the lower surfaces of the plurality of lower connection pads 122LP). For example, the lower solder resist layer 134 may cover a part of the lower surface of each of the plurality of substrate wiring patterns 122 adjacent to side surfaces of each of the plurality of lower connection pads 122LP, but may not cover the remaining part of the lower surfaces, and the substrate wiring patterns 122 of which at least a part of the lower surfaces are not covered by the lower surface solder resist layer 134 may be the plurality of lower connection pads 122LP.

A plurality of package connection terminals 150 may be attached to the lower surface of the package substrate 100. The plurality of package connection terminals 150 may be attached to the plurality of lower connection pads 122LP. In some embodiments, the plurality of package connection terminals 150 may completely cover surfaces of the plurality of lower connection pads 122LP that are not covered by the lower solder resist layer 134, for example, at least a part of the lower surfaces of the plurality of lower connection pads 122LP. A height HT of each of the plurality of package connection terminals 150 may be about 80 μm or more. For example, the height HT of the package connection terminal 150 may be about 80 μm to about 350 μm. A horizontal width WT of the package connection terminal 150 may be about 80 μm or more. For example, the horizontal width WT of the package connection terminal 150 may be about 80 μm to about 350 μm. In some embodiments, the height HT of the package connection terminal 150 may be about 180 μm to about 350 μm. In some embodiments, the horizontal width WT of the package connection terminal 150 may be about 180 μm to about 350 μm. A separation interval IV between two adjacent package connection terminals 150 among the plurality of package connection terminals 150 may have a value equal to or greater than the horizontal width WT of the package connection terminal 150. For example, the separation interval IV between the two adjacent package connection terminals 150 among the plurality of package connection terminals 150 may be about 80 μm to about 500 μm. In some embodiments, the separation interval IV between the two adjacent package connection terminals 150 among the plurality of package connection terminals 150 may be about 180 μm to about 500 μum.

Alternatively, among conductive material layers disposed on the upper surface of the at least one substrate base 110, parts not covered by the upper solder resist layer 132 may be referred to as the plurality of upper connection pads 122UP, and only a part connected to the plurality of upper connection pads 122UP and covered by the upper solder resist layer 132 may be referred to as the uppermost substrate wiring pattern 122 among the plurality of substrate wiring patterns 122. Similarly, among the conductive material layers disposed on the lower surface of the at least one substrate base 110, parts not covered by the lower solder resist layer 134 may be referred to as the plurality of lower connection pads 122LP, and only a part connected to the plurality of lower connection pads 122LP and covered by the lower resist layer 134 may be referred to as the lowermost substrate wiring pattern 122 among the plurality of substrate wiring patterns 122. The substrate wiring structure 120 including the plurality of substrate wiring patterns 122 and the plurality of substrate via patterns 124 may electrically connect the plurality of upper connection pads 122UP to the plurality of lower connection pads 122LP.

In some embodiments, the package substrate 100 may be a redistribution structure including a plurality of redistribution patterns including a plurality of redistribution lines and a plurality of redistribution vias, instead of the substrate wiring structure 120 including the plurality of substrate wiring patterns 122 and the plurality of substrate via patterns 124 and a redistribution insulating layer surrounding the redistribution lines and the redistribution vias, instead of the substrate base 110.

The plurality of first semiconductor chips 200 may be sequentially stacked in the vertical direction (Z direction) on the package substrate 100. The plurality of first semiconductor chips 200 may be stacked in a step form at intervals in the horizontal direction as shown, e.g., in FIG. 1. Each of the plurality of first semiconductor chips 200 may have a rectangular planar shape. In some embodiments, the plurality of first semiconductor chips 200 may be stacked in a step form at intervals along one side of a rectangle. In some embodiments, the plurality of first semiconductor chips 200 may be stacked at intervals in the diagonal direction of a rectangle. In some embodiments, some of the plurality of first semiconductor chips 200 may be stacked in a step form at intervals in one direction, and others of the plurality of first semiconductor chips 200 may be stacked in a step form at intervals in a direction opposite to the one direction on some of the plurality of first semiconductor chips 200.

Each of the plurality of first semiconductor chips 200 may include a first semiconductor substrate 210. The first semiconductor substrate 210 may include a semiconductor material such as a group IV semiconductor material, a group III-V semiconductor material, a group II-VI semiconductor material, or a group II-VI oxide semiconductor material. For example, the first semiconductor substrate 210 may include silicon (Si). Alternatively, the first semiconductor substrate 210 may be a semiconductor device such as germanium (Ge), or a compound semiconductor such as silicon carbide (SiC), gallium arsenide (GaAs), indium arsenide (InAs), and indium phosphide (InP). Alternatively, the first semiconductor substrate 210 may have a silicon on insulator (SOI) structure. For example, the first semiconductor substrate 210 may include a buried oxide BOX layer. The first semiconductor substrate 210 may include a conductive region, for example, a well doped with impurities. The first semiconductor substrate 210 may have various device isolation structures, such as a shallow trench isolation (STI) structure. The first semiconductor substrate 210 may have an active surface and an inactive surface opposite to the active surface.

The first semiconductor chip 200 may have a first semiconductor device 205 including a plurality of individual devices of various types formed on the active surface. The plurality of individual devices may include various microelectronic devices, such as a metal-oxide-semiconductor field effect transistor (MOSFET) such as a complementary metal-insulator-semiconductor (CMOS) transistor, an image sensor such as system large scale integration (LSI), a CMOS imaging sensor (CIS), etc., a micro-electro-mechanical system (MEMS), an active device, a passive device, etc. The plurality of individual devices may be electrically connected to the conductive region of the first semiconductor substrate 210. The first semiconductor device 205 may further include a conductive wiring or a conductive plug electrically connecting at least two of the plurality of individual devices, or connecting the plurality of individual devices to the conductive region of the first semiconductor substrate 210. Additionally, each of the plurality of individual devices may be electrically separated from other neighboring individual devices by an insulating layer.

The first semiconductor device 205 may be a memory semiconductor device. For example, the first semiconductor chip 200 may be a memory semiconductor chip. In some embodiments, the memory semiconductor device may be a non-volatile memory semiconductor device such as flash memory, phase-change random access memory (PRAM), magnetoresistive random access memory (MRAM), ferroelectric random access memory (FeRAM), or resistive random access memory (RRAM). The flash memory may be, for example, V-NAND flash memory. In some embodiments, the memory semiconductor device may be a volatile memory semiconductor chip such as Dynamic Random Access Memory (DRAM) or Static Random Access Memory (SRAM).

The plurality of first semiconductor chips 200 may respectively include a plurality of first chip pads 230 respectively disposed on the upper surfaces of the plurality of first semiconductor chips 200. For example, each of the plurality of first chip pads 230 may be disposed on the active surface of each of the plurality of first semiconductor chips 200. The plurality of first semiconductor chips 200 may be stacked on the package substrate 100 so that the active surface faces upward, that is, in a direction opposite to the package substrate 100. The plurality of first semiconductor chips 200 may be stacked on the package substrate 100 so that the inactive surface of the first semiconductor substrate 210 faces downward, that is, toward the package substrate 100.

A plurality of first bonding wires 610 may be connected between the plurality of first chip pads 230 and the plurality of first upper connection pads 122UPa. The first semiconductor chip 200 may be electrically connected to the package substrate 100 through the plurality of first bonding wires 610.

The plurality of first bonding wires 610 may sequentially connect the plurality of first chip pads 230 of each of the first semiconductor chips 200 to each other from the plurality of first chip pads 230 of the uppermost first semiconductor chip 200 to the plurality of first chip pads 230 of the lowermost first semiconductor chip 200 and then, connect the plurality of first chip pads 230 of the lowermost first semiconductor chip 200 to the plurality of first upper connection pads 122UPa.

The plurality of first semiconductor chips 200 may be attached onto lower structures with a plurality of first die adhesive films 280 attached to lower surfaces therebetween. For example, the lowermost first semiconductor chip 200 among the plurality of first semiconductor chips 200 may be attached onto the package substrate 100 with the first die adhesive film 280 therebetween, and each of the remaining first semiconductor chips 200 may be attached onto the next lowest first semiconductor chip 200 with the first die adhesive film 280 therebetween. The first die adhesive film 280 may include, for example, an inorganic adhesive or a polymer adhesive. The polymer adhesive may include, for example, a thermosetting polymer or a thermoplastic polymer. The thermosetting resin has a three-dimensional cross-link structure after a monomer is thermally molded and does not soften even when reheated. In contrast, the thermoplastic polymer exhibits plasticity by heating and has a structure of a linear polymer. In addition, the polymer adhesive may be of a hybrid type by mixing these two components.

The at least one second semiconductor chip 300 may be attached onto the package substrate 100 so as to be spaced apart from the plurality of first semiconductor chips 200. For example, the at least one second semiconductor chip 300 may be attached onto the package substrate 100 so as to be spaced apart from the plurality of first semiconductor chips 200 and the lowermost first semiconductor chip 200 in the horizontal direction.

The at least one second semiconductor chip 300 may include a second semiconductor substrate 310. The second semiconductor substrate 310 may include the same material as the first semiconductor substrate 210. For example, the second semiconductor substrate 310 may include a semiconductor material such as a group IV semiconductor material, a group III-V semiconductor material, a group II-VI semiconductor material, or a group II-VI oxide semiconductor material. For example, the second semiconductor substrate 310 may include silicon. The second semiconductor substrate 310 may have an active surface and an inactive surface opposite to the active surface. The at least one second semiconductor chip 300 may have a second semiconductor device 305 including a plurality of individual devices of various types formed on the active surface. The second semiconductor device 305 may control access to data stored in the plurality of first semiconductor chips 200. That is, the second semiconductor device 305 may control write/read operations of the plurality of first semiconductor chips 200, for example, flash memory, etc., according to control commands of an external host. The second semiconductor device 305 may perform wear leveling, garbage collection, bad block management, and error correction code (ECC), for a non-volatile memory semiconductor chip.

The at least one second semiconductor chip 300 may include a plurality of second chip pads 330 disposed on the active surface.

In some embodiments, the at least one second semiconductor chip 300 may be attached onto the package substrate 100 so that the active surface faces upward, that is, in a direction opposite to the package substrate 100. The at least one second semiconductor chip 300 may be stacked on the package substrate 100 so that the inactive surface of the second semiconductor substrate 310 faces downward, that is, toward the package substrate 100. The plurality of second bonding wires 620 may be connected between the plurality of second chip pads 330 and the plurality of second upper connection pads 122UPb. The second semiconductor chip 300 may be electrically connected to the package substrate 100 through the plurality of second bonding wires 620. The at least one second semiconductor chip 300 may be attached onto the package substrate 100 with a second die adhesive film 380 attached to a lower surface thereof. The second die adhesive film 380 may include the same material as the first die adhesive film 280. For example, the second die adhesive film 380 may include an inorganic adhesive or a polymer adhesive.

In some embodiments, the at least one second semiconductor chip 300 may be attached onto the package substrate 100 so that the active surface faces downward, that is, toward the package substrate 100. A plurality of chip connection terminals may be attached to the plurality of second chip pads 330. The plurality of chip connection terminals may be, for example, solder balls or bumps. The plurality of chip connection terminals may be disposed between the plurality of second upper connection pads 122UPb and the plurality of second chip pads 330 to electrically connect the at least one second semiconductor chip 300 to the package substrate 100. In some embodiments, an underfill material layer surrounding the plurality of chip connection terminals may be disposed between the at least one second semiconductor chip 300 and the package substrate 100. The underfill material layer may include, for example, an epoxy resin formed using a capillary under-fill method. In some embodiments, the underfill material layer may be a non-conductive film (NCF).

A molding layer 500 covering the upper surface of the package substrate 100 and surrounding the plurality of first semiconductor chips 200, the at least one second semiconductor chip 300, and the plurality of bonding wires 600 may be disposed on the package substrate 100. The molding layer 500 may be a molding member including, for example, an epoxy mold compound (EMC).

The electromagnetic shielding layer 900 may integrally cover the side surfaces of the package substrate 100 and the side surfaces and an upper surface of the molding layer 500. In some embodiments, the electromagnetic shielding layer 900 may be formed using a conformal shielding method. For example, the electromagnetic shielding layer 900 may be formed to have a generally constant thickness. The electromagnetic shielding layer 900 may shield electromagnetic waves radiated from the plurality of first semiconductor chips 200 and the at least one second semiconductor chip 300 and electromagnetic waves radiated from the side surfaces of the package substrate 100. In some embodiments, the electromagnetic shielding layer 900 may be connected to the substrate wiring pattern 122 that is provided with a ground among the plurality of substrate wiring patterns 122. For example, at least one of the plurality of substrate wiring patterns 122 may be exposed to (e.g., connected to or in contact with) the side surfaces of the package substrate 100 and may be provided with the ground.

In some embodiments, the electromagnetic shielding layer 900 may completely cover the side surfaces of the package substrate 100, but may not cover the lower surface thereof. For example, the electromagnetic shielding layer 900 may completely cover side surfaces of the substrate base 110, the upper solder resist layer 132, and the lower solder resist layer 134. In some embodiments, the lowermost end of the electromagnetic shielding layer 900 may be located at the same vertical level as the lower surface of the package substrate 100. For example, the lowermost end of the electromagnetic shielding layer 900 may be located at the same vertical level as a part of the lower surface of the package substrate 100 on an edge side of the package substrate 100. For example, the lowermost end of the electromagnetic shielding layer 900 may be located at the same vertical level as a part of the lower surface of the package substrate 100 that is adjacent to the edge of the package substrate 100.

For example, the lowermost end of the lower solder resist layer 134 and the lowermost end of the electromagnetic shielding layer 900 may be located at the same vertical level at the edge side of (e.g., adjacent to the edge of) the package substrate 100.

In some embodiments, the electromagnetic shielding layer 900 may be formed using, for example, a physical vapor deposition (PVD) method. For example, the electromagnetic shielding layer 900 may be formed through a sputtering process. For example, the electromagnetic shielding layer 900 may include a metal material such as copper (Cu) or stainless steel. In some embodiments, the electromagnetic shielding layer 900 may have a stack structure in which a stainless steel layer covers each of an upper surface and a lower surface of a copper layer. In some embodiments, the electromagnetic shielding layer 900 may be formed using, for example, a spray method. For example, the electromagnetic shielding layer 900 may include a metal material such as silver. In some embodiments, the electromagnetic shielding layer 900 may include a metal layer including silver and a carbon nanotube (CNT) layer disposed between the metal layer, the package substrate 100, and the molding layer 500.

The semiconductor package 1 according to the inventive concept includes the electromagnetic shielding layer 900 that completely covers the upper side and the side surfaces of the molding layer 500 and the side surfaces of the package substrate 100, thereby preventing reliability of an electronic device including the semiconductor package 1 from being reduced due to disturbances such as electromagnetic noise or malfunction caused by the semiconductor package 1.

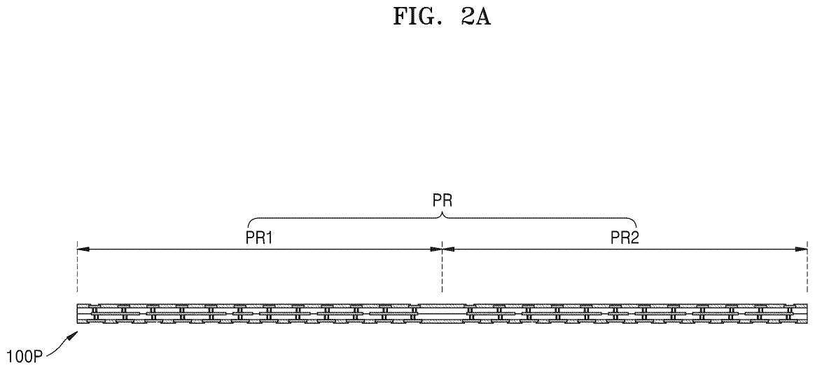

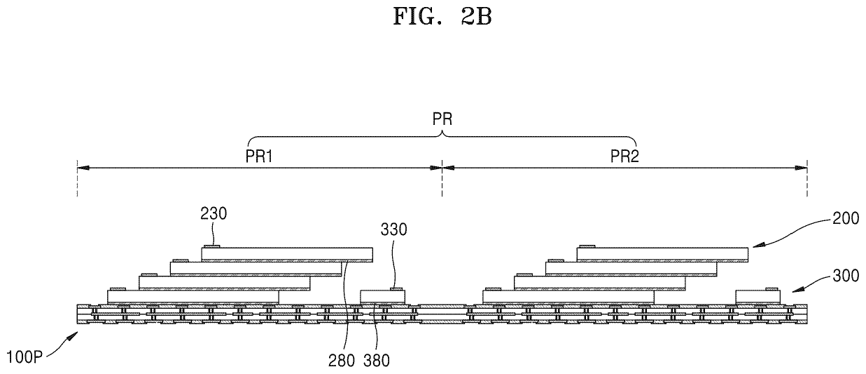

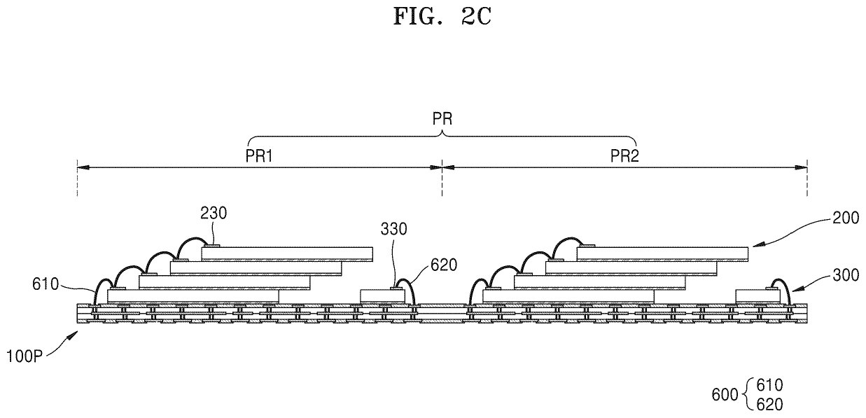

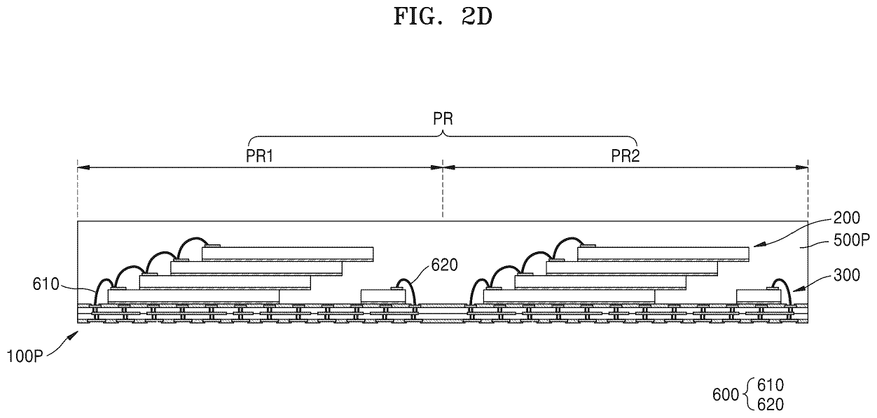

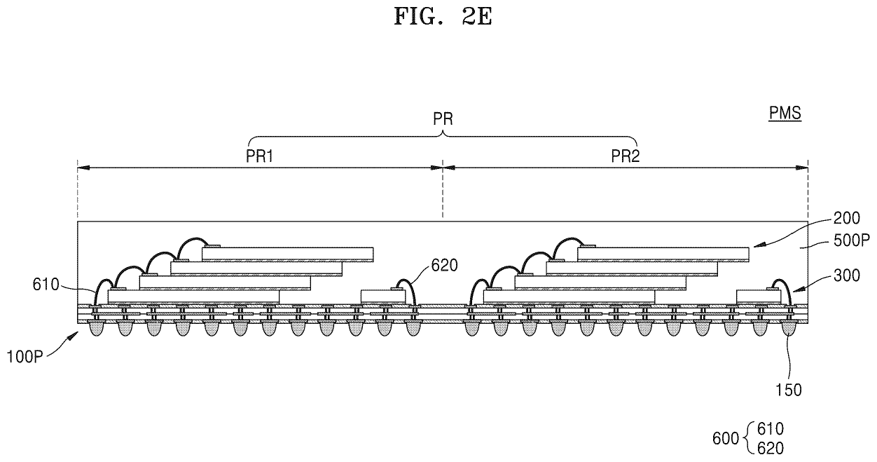

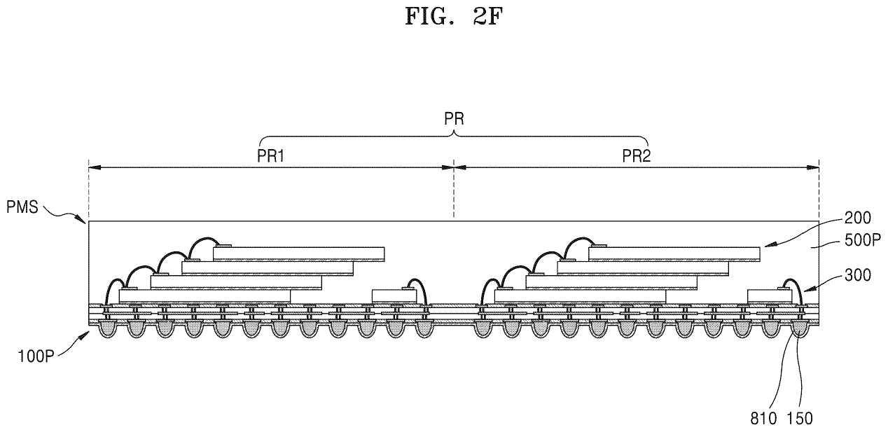

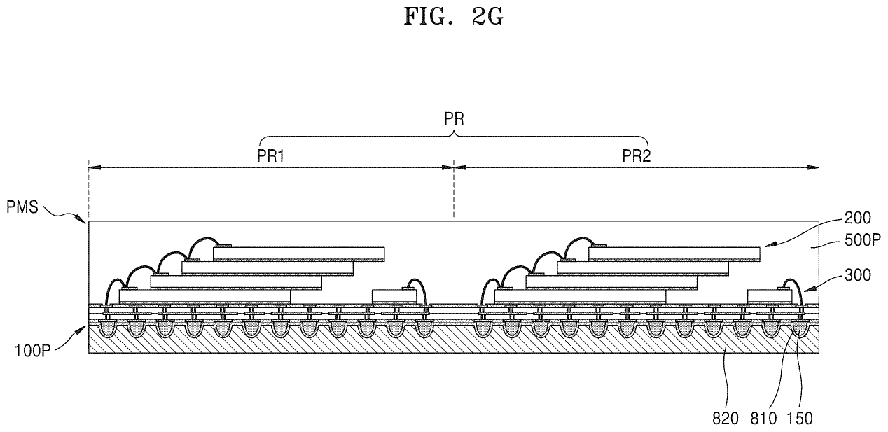

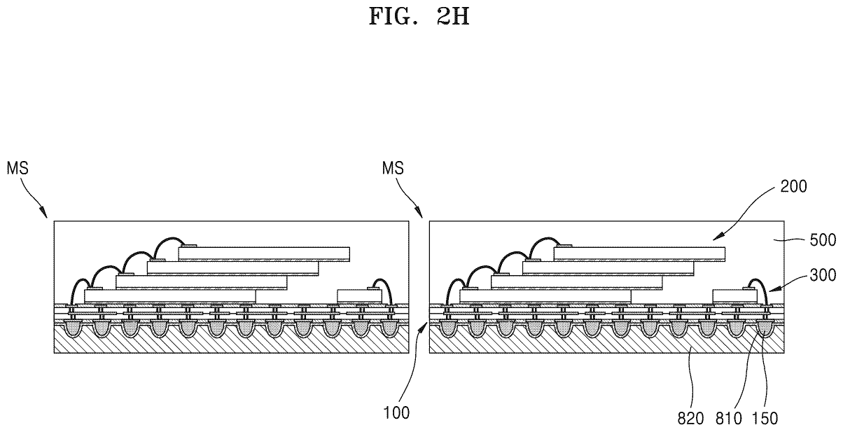

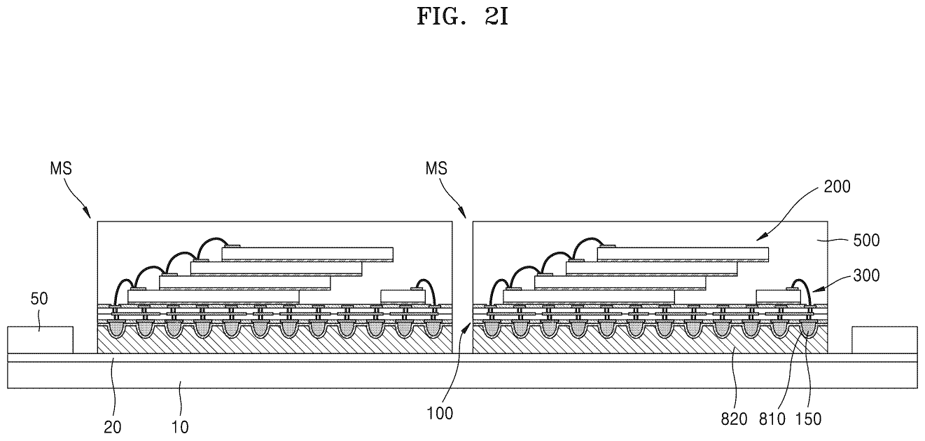

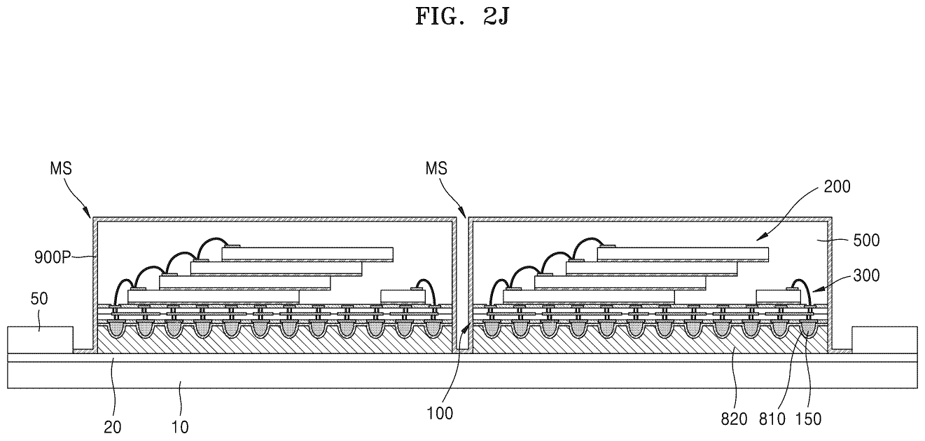

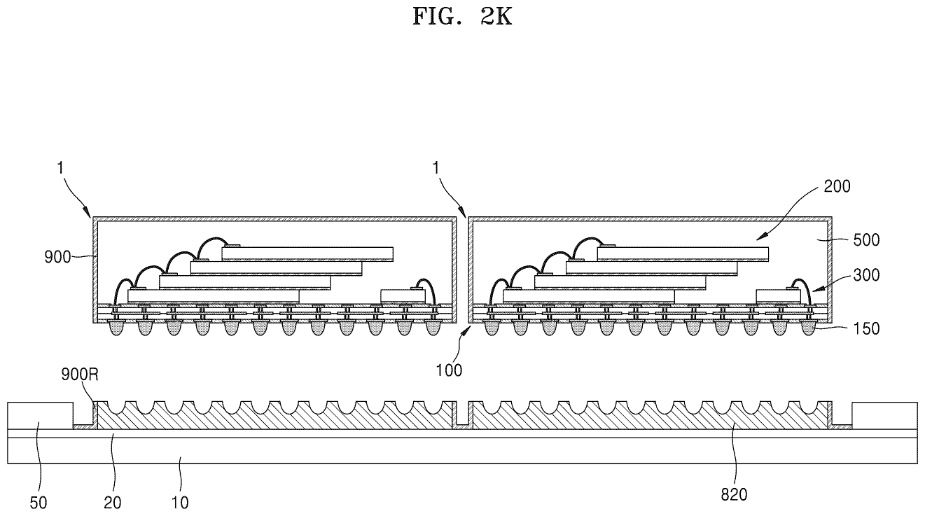

FIGS. 2A to 2K are cross-sectional views showing a method of manufacturing a semiconductor package according to an embodiment. FIGS. 2A to 2K may be described with reference to FIG. 1.

Referring to FIG. 2A, a preliminary package substrate 100P including a plurality of package regions PR is prepared. The plurality of package regions PR includes a first package region PR1 and a second package region PR2. Each of the plurality of package regions PR of the preliminary package substrate 100P, for example, each of the first package region PR1 and the second package region PR2, may correspond to a respective one of a plurality of the package substrates 100 shown in FIG. 1.

The preliminary package substrate 100P may include the at least one substrate base 110 and the substrate wiring structure 120. In some embodiments, the preliminary package substrate 100P may include the plurality of substrate bases 110 that are stacked. The substrate wiring structure 120 may include the plurality of substrate wiring patterns 122 disposed on the upper surface and the lower surface of the substrate base 110 or disposed inside the substrate base 110 and extending in the horizontal direction, and the plurality of substrate via patterns 124 penetrating at least a part of the at least one substrate base 110 and extending in the vertical direction so as to electrically connect between the two substrate wiring patterns 122 located at different vertical levels among the plurality of substrate wiring patterns 122. The preliminary package substrate 100P may further include the solder resist layer 130 covering the upper surface and the lower surface of the at least one substrate base 110. The solder resist layer 130 may include the upper solder resist layer 132 covering the upper surface of the at least one substrate base 110 and the lower solder resist layer 134 covering the lower surface of the at least one substrate base 110. Some parts of the substrate wiring patterns 122 disposed on the upper surface of the at least one substrate base 110 may be the plurality of upper connection pads 122UP. The plurality of upper connection pads 122UP may include the first upper connection pad 122UPa and the second upper connection pad 122UPb. Some parts of the substrate wiring patterns 122 disposed on the lower surface of the at least one substrate base 110 may be the plurality of lower connection pads 122LP.

Referring to FIG. 2B, the plurality of first semiconductor chips 200 and the at least one second semiconductor chip 300 are attached to each of the plurality of package regions PR of the preliminary package substrate 100P, for example, each of the first package region PR1 and the second package region PR2. For example, a respective plurality of first semiconductor chips 200 and a respective at least one second semiconductor chip 300 may be attached to each of the plurality of package regions PR of the preliminary package substrate 100P.

The plurality of first semiconductor chips 200 may be sequentially stacked in the vertical direction (Z direction) on the preliminary package substrate 100P. The plurality of first semiconductor chips 200 may be stacked in a step form at intervals in the horizontal direction. The plurality of first semiconductor chips 200 may respectively include the plurality of first chip pads 230 respectively disposed on the upper surfaces of the plurality of first semiconductor chips 200. For example, each of the plurality of first chip pads 230 may be disposed on the active surface of each of the plurality of first semiconductor chips 200. The plurality of first semiconductor chips 200 may be stacked on the preliminary package substrate 100P so that the active surface faces upward, that is, in a direction opposite to the preliminary package substrate 100P. The plurality of first semiconductor chips 200 may be stacked on the preliminary package substrate 100P so that the inactive surface of the first semiconductor substrate 210 faces downward, that is, toward the preliminary package substrate 100P. The plurality of first semiconductor chips 200 may be attached onto lower structures with the plurality of first die adhesive films 280 attached to lower surfaces therebetween. For example, the lowermost first semiconductor chip 200 among the plurality of first semiconductor chips 200 may be attached onto the preliminary package substrate 100P with the first die adhesive film 280 therebetween, and each of the remaining first semiconductor chips 200 may be attached onto the next lowest first semiconductor chip 200 with the first die adhesive film 280 therebetween.

The at least one second semiconductor chip 300 may be attached onto the preliminary package substrate 100P so as to be spaced apart from the plurality of first semiconductor chips 200. For example, the at least one second semiconductor chip 300 may be attached onto the preliminary package substrate 100P so as to be spaced apart from the plurality of first semiconductor chips 200 and the lowermost first semiconductor chip 200 in the horizontal direction. The at least one second semiconductor chip 300 may include a plurality of second chip pads 330 disposed on the active surface. In some embodiments, the at least one second semiconductor chip 300 may be attached onto the preliminary package substrate 100P so that the active surface faces upward, that is, in a direction opposite to the preliminary package substrate 100P. The at least one second semiconductor chip 300 may be stacked on the preliminary package substrate 100P so that the inactive surface of the second semiconductor substrate 310 faces downward, that is, toward the preliminary package substrate 100P. The at least one second semiconductor chip 300 may be attached onto the preliminary package substrate 100P with a second die adhesive film 380 attached to a lower surface thereof.

In some other embodiments, at least one second semiconductor chip 300 may be attached to the preliminary package substrate 100P with the active surface facing downward, that is, toward the preliminary package substrate 100P.

In some embodiments, the at least one second semiconductor chip 300 may first be attached onto the preliminary package substrate 100P, and then, the plurality of first semiconductor chips 200 may be attached onto the preliminary package substrate 100P. In some embodiments, the plurality of first semiconductor chips 200 may be attached onto the preliminary package substrate 100P, and then, the at least one second semiconductor chip 300 may be attached onto the preliminary package substrate 100P.

Referring to FIG. 2C, the plurality of first semiconductor chips 200 and the at least one second semiconductor chip 300 are attached onto each of the plurality of package regions PR of the preliminary package substrate 100P, and then, the plurality of bonding wires 600 electrically connecting the plurality of first semiconductor chips 200 and the at least one second semiconductor chip 300 to the preliminary package substrate 100P are formed. The plurality of bonding wires 600 may include the first bonding wire 610 and the second bonding wire 620.

The plurality of first bonding wires 610 may be connected between the plurality of first chip pads 230 and the plurality of first upper connection pads 122UPa. The first semiconductor chip 200 may be electrically connected to the preliminary package substrate 100P through the plurality of first bonding wires 610. The plurality of first bonding wires 610 may sequentially connect the plurality of first chip pads 230 of each of the first semiconductor chips 200 to each other from the plurality of first chip pads 230 of the uppermost first semiconductor chip 200 to the plurality of first chip pads 230 of the lowermost first semiconductor chip 200 and then, connect the plurality of first chip pads 230 of the lowermost first semiconductor chip 200 to the plurality of first upper connection pads 122UPa.

The plurality of second bonding wires 620 may be connected between the plurality of second chip pads 330 and the plurality of second upper connection pads 122UPb. The second semiconductor chip 300 may be electrically connected to the preliminary package substrate 100P through the plurality of second bonding wires 620.

Referring to FIG. 2D, a preliminary molding layer 500P is formed covering the upper surface of the preliminary package substrate 100P, and the preliminary molding layer 500P surrounds the plurality of first semiconductor chips 200, the at least one second semiconductor chip 300, and the plurality of bonding wires 600. The preliminary molding layer 500P may include, for example, EMC.

Referring to FIG. 2E, the plurality of package connection terminals 150 are attached to the plurality of lower connection pads 122LP of the preliminary package substrate 100P. The preliminary package substrate 100P, the plurality of first semiconductor chips 200 and the at least one second semiconductor chip 300, the plurality of bonding wires 600, the preliminary molding layer 500P, and the plurality of package connection terminals 150 may be collectively referred to as a package molding structure PMS.

Referring to FIG. 2F, a release layer 810 covering the lower surface of the preliminary package substrate 100P and the plurality of package connection terminals 150 is formed. The release layer 810 may be formed to conformally cover the lower surface of the preliminary package substrate 100P and to conformally cover surfaces of the plurality of package connection terminals 150. For example, the release layer 810 may be formed to cover the lower surface of the preliminary package substrate 100P and the surfaces of the plurality of package connection terminals 150 at a generally constant thickness of about 3 μm to about 10 μm. In some embodiments, the release layer 810 may be formed using a coating method. For example, the release layer 810 may be formed using a slit coating method. For example, the release layer 810 may conformally cover the plurality of package connection terminals 150 such that protrusions are formed in the release layer 810 corresponding to the positions of the plurality of package connection terminals 150.

The release layer 810 may include a material that is photodecomposable by light energy and has a heat resistance function. For example, the release layer 810 may include a material that is photodecomposable by light energy such as laser or ultraviolet (UV) light. For example, the release layer 810 may include a material that has a heat resistance function at a temperature of about 250° C. or higher. In some embodiments, the release layer 810 may include a material that is photodecomposable by an excimer laser with a wavelength of about 308 nm or UV light with a wavelength of about 254 nm. For example, the release layer 810 may include polyamic acid (PAA) that is photodecomposable by an excimer laser with a wavelength of about 308 nm, or tetrazole and derivatives thereof, tetrazolone and derivatives thereof, triazole and derivatives thereof, or acyl azide and derivatives thereof that is photodecomposable by UV light with a wavelength of about 254 nm.

Referring to FIG. 2G, an adhesive layer 820 covering the release layer 810 and surrounding the plurality of package connection terminals 150 is formed on the lower surface of the preliminary package substrate 100P. The adhesive layer 820 may be formed to have a thickness that may surround the plurality of package connection terminals 150. For example, the thickness of the adhesive layer 820 may have a value greater than the height of the plurality of package connection terminals 150. For example, the adhesive layer 820 may cover the lowermost surfaces of the plurality of package connection terminals 150 and may also horizontally surround the plurality of package connection terminals 150. For example, the adhesive layer 820 may be formed to have a thickness of about 100 μm to about 500 μm. In some embodiments, the adhesive layer 820 may be formed to have a thickness of about 250 μm to about 500 μm. In some embodiments, the adhesive layer 820 may be formed by applying and curing a glue by using a coating method.

The adhesive layer 820 may include a curable polymer. For example, the adhesive layer 820 may include a thermosetting polymer or a photocurable polymer. The adhesive layer 820 may include a polymer that may be cured by thermal energy or light energy. For example, the adhesive layer 820 may include a polymer that may be thermally cured at a temperature of about 150° C. or higher or photocured by UV light at about 365 nm. In some embodiments, the adhesive layer 820 may include a thermosetting siloxane polymer that may be thermally cured at a temperature of about 150° C. or higher, or a heat resistant functional polymer including an acryl binder with a vinyl group substituent that may be photocured by UV light at about 365 nm, for example, a photocurable silicone acryl polymer. For example, the adhesive layer 820 may be formed to have a modulus of less than 30 MPa. In some embodiments, the adhesive layer 820 may be formed to have a modulus of about 5 MPa to about 10 MPa.

Referring to FIGS. 2G and 2H together, the package molding structure PMS in which the release layer 810 and the adhesive layer 820 are formed is separated such that each of the separated portions corresponds to a respective package region of the plurality of package regions PR to form a plurality of molding structures MS. Each molding structure MS of the plurality of molding structures MS includes the package substrate 100, the plurality of first semiconductor chips 200, the at least one second semiconductor chip 300, the plurality of bonding wires 600, the plurality of package connection terminals 150, the release layer 810, and the adhesive layer 820. The plurality of molding structures MS may be formed by performing a sawing process to cut the preliminary molding layer 500P, the preliminary package substrate 100P, the release layer 810, and the adhesive layer 820 included in the package molding structure PMS. Each of the plurality of package regions PR included in the preliminary package substrate 100P shown in FIG. 2A may be separated from each other to form package substrates 100. Each of the plurality of molding structures MS may include the package substrate 100 corresponding to each of the plurality of package regions PR, the plurality of first semiconductor chips 200 and the at least one second semiconductor chip 300 disposed on the upper surface of the package substrate 100, the plurality of bonding wires 600, the molding layer 500, and the plurality of package connection terminals 150, the release layer 810, and the adhesive layer 820 which are disposed on the lower surface of the package substrate 100.

Referring to FIG. 2I, the plurality of molding structures MS are attached onto the support structure 10 having an upper surface to which a heat resistant tape 20 is attached. The plurality of molding structures MS may be attached onto the support structure 10 to which the heat resistant tape 20 is attached so as to be spaced apart from each other in the horizontal direction. In some embodiments, a guide structure 50 surrounding the plurality of molding structures MS may be attached onto the support structure 10 to which the heat resistant tape 20 is attached.

Referring to FIG. 2J, a preliminary electromagnetic shielding layer 900P covering an upper surface and side surfaces of each of the plurality of molding structures MS is formed. For example, the preliminary electromagnetic shielding layer 900P may be formed to cover the side surfaces of each of the release layer 810, the adhesive layer 820, and the package substrate 100 and the side surfaces and the upper surface of the molding layer 500 included in each of the plurality of molding structures MS. In some embodiments, the preliminary electromagnetic shielding layer 900P may further cover the support structure 10 to which the heat resistant tape 20 is attached. In some embodiments, the preliminary electromagnetic shielding layer 900P may be formed using a conformal shielding method. For example, the preliminary electromagnetic shielding layer 900P may be formed to have a generally constant thickness. In some embodiments, the preliminary electromagnetic shielding layer 900P may be formed using, for example, a physical vapor deposition method. For example, the preliminary electromagnetic shielding layer 900P may be formed through a sputtering process. In some embodiments, the preliminary electromagnetic shielding layer 900P may be formed through a sputtering process with a process temperature of about 200° C. For example, the preliminary electromagnetic shielding layer 900P may be formed to include a metal material such as copper (Cu) or stainless steel. In some embodiments, the preliminary electromagnetic shielding layer 900P may be formed to have a stack structure in which a stainless steel layer covers an upper surface and a lower surface of a copper layer.

Referring to FIGS. 2J and 2K, light energy is transmitted to the release layer 810 by laser or UV light to photodecompose the release layer 810 so that the plurality of semiconductor packages 1 each including the package substrate 100, the plurality of first semiconductor chips 200 and the at least one second semiconductor chip 300, the plurality of bonding wires 600, the molding layer 500, the plurality of package connection terminals 150, and the electromagnetic shielding layer 900 are separated from the adhesive layer 820.

For example, the release layer 810 may be photodecomposed by an excimer laser with a wavelength of 308 nm or UV light with a wavelength of about 254 nm to generate gas. In order to promote photodecomposition of the release layer 810, the process temperature may be about 150° C. or higher and laser or UV light may be irradiated. The package substrate 100 and the plurality of package connection terminals 150 may be separated from the adhesive layer 820 by the gas generated from the release layer 810. In addition, the preliminary electromagnetic shielding layer 900P may be separated into a first portion, which is the electromagnetic shielding layer 900 covering the package substrate 100 and the molding layer 500, and a second portion, which is a residual shielding layer 900R covering the adhesive layer 820 by the gas generated from the release layer 810. In some embodiments, the residual shielding layer 900R may cover the adhesive layer 820 and the support structure 10 to which the heat resistant tape 20 is attached.

The electromagnetic shielding layer 900 may integrally cover the side surface of the package substrate 100 and the side surfaces and the upper surface of the molding layer 500. The electromagnetic shielding layer 900 may completely cover the side surfaces of the package substrate 100, but may not cover the lower surface thereof. For example, the electromagnetic shielding layer 900 may completely cover side surfaces of the substrate base 110, the upper solder resist layer 132, and the lower solder resist layer 134. For example, the lowermost end of the electromagnetic shielding layer 900 may be located at the same vertical level as the lower (e.g., lowermost) surface of the package substrate 100. For example, the lowermost end of the solder resist layer 134 and the lowermost end of the electromagnetic shielding layer 900 may be located at the same vertical level at an edge side of (e.g., adjacent to an edge of) the package substrate 100.

Referring to FIG. 1 and FIGS. 2A to 2K together, the method of manufacturing the semiconductor package 1 according to the inventive concept uses the release layer 810 that is photodecomposed to generate gas and the adhesive layer 820 including a curable polymer. The adhesive layer 820 is formed by applying and curing a glue by using a coating method, and thus, even though sizes of the plurality of package connection terminals 150, for example, the horizontal width WT and/or the height HT, increase, the plurality of package connection terminals 150 may be impregnated. In addition, the release layer 810 is photodecomposed and generates gas, thereby easily separating the semiconductor package 1 from the adhesive layer 820, and preventing a burr that protrudes in the shape of a band from being generated in the electromagnetic shielding layer 900 included in the semiconductor package 1 without being clearly cut when separated from the preliminary electromagnetic shielding layer 900P.

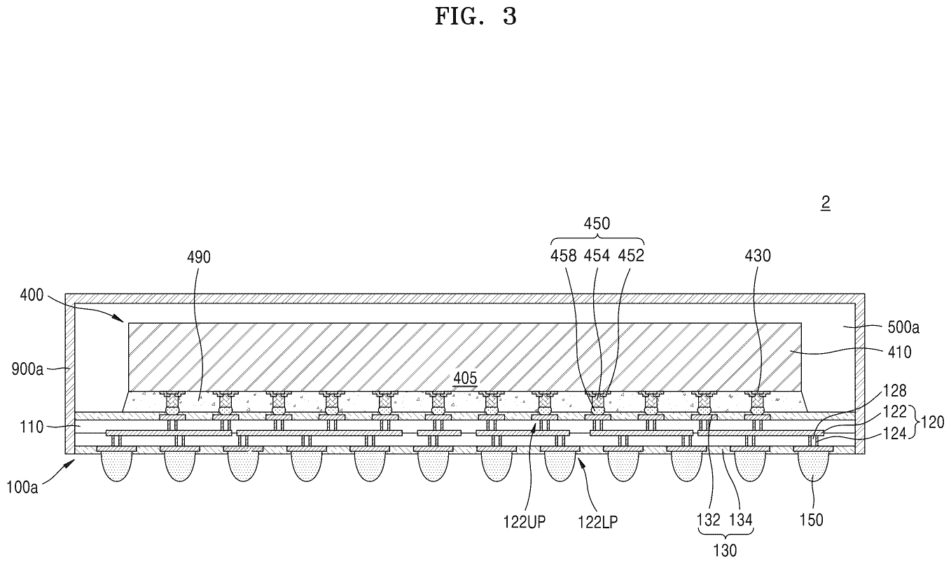

FIG. 3 is a cross-sectional view showing a semiconductor package 2 according to an embodiment.

Referring to FIG. 3, the semiconductor package 2 includes a package substrate 100a, at least one semiconductor chip 400, a molding layer 500a, and an electromagnetic shielding layer 900a. The at least one semiconductor chip 400 may be attached to the package substrate 100a. The molding layer 500a may surround the at least one semiconductor chip 400 on the package substrate 100a. The electromagnetic shielding layer 900a may cover the package substrate 100a and the molding layer 500a.

In some embodiments, the package substrate 100a may be a printed circuit board. For example, the package substrate 100a may be a double-sided printed circuit board or a multi-layer printed circuit board. The package substrate 100a may include the at least one substrate base 110 and the substrate wiring structure 120. The package substrate 100a is generally the same as the package substrate 100 shown in FIG. 1, and thus, a redundant description thereof may be omitted. The substrate wiring structure 120 may include the plurality of substrate wiring patterns 122 disposed on the upper surface and the lower surface of the substrate base 110 or disposed inside the substrate base 110 and extending in a horizontal direction, and the plurality of substrate via patterns 124 penetrating at least a part of the at least one substrate base 110 and extending in a vertical direction so as to electrically connect two substrate wiring patterns 122 located at different vertical levels among the plurality of substrate wiring patterns 122. Some parts of the substrate wiring patterns 122 disposed on an upper surface of the at least one substrate base 110 may be the plurality of upper connection pads 122UP. A plurality of chip terminals 450 may be attached to the plurality of upper connection pads 122UP. Some parts of the substrate wiring patterns 122 disposed on a lower surface of the at least one substrate base 110 may be the plurality of lower connection pads 122LP. The plurality of package connection terminals 150 may be attached to the plurality of lower connection pads 122LP.

In some embodiments, the package substrate 100a may be a redistribution structure including a plurality of redistribution patterns including a plurality of redistribution lines and a plurality of redistribution vias, instead of the substrate wiring structure 120 including the plurality of substrate wiring patterns 122 and the plurality of substrate via patterns 124 and a redistribution insulating layer surrounding the redistribution lines and the redistribution vias, instead of the substrate base 110.

The at least one semiconductor chip 400 may include a semiconductor substrate 410. The semiconductor substrate 410 may include the same material as each of the first semiconductor substrate 210 or the second semiconductor substrate 310 shown in FIG. 1. For example, the semiconductor substrate 410 may include a semiconductor material such as a group IV semiconductor material, a group III-V semiconductor material, a group II-VI semiconductor material, or a group II-VI oxide semiconductor material. For example, the semiconductor substrate 410 may include silicon. The semiconductor substrate 410 may have an active surface and an inactive surface that are opposite to each other.

A semiconductor device 405 may be formed on the active surface of the semiconductor substrate 410. The semiconductor device 405 may be a logic device or a memory device. The memory device may be a volatile memory device or a non-volatile memory device. In some embodiments, the semiconductor chip 400 may include a logic device. For example, the semiconductor chip 400 may be a central processing unit (CPU) chip, a graphics processing unit (GPU) chip, or an application processor (AP) chip. In some embodiments, the semiconductor chip 400 may be a memory semiconductor chip including a memory device. For example, the memory device may be a non-volatile memory semiconductor device such as flash memory, phase-change random access memory (PRAM), magnetoresistive random access memory (MRAM), ferroelectric random access memory (FeRAM), or resistive random access memory (RRAM). The flash memory may be, for example, NAND flash memory or V-NAND flash memory. In some embodiments, the memory device may be a volatile memory semiconductor chip such as Dynamic Random Access Memory (DRAM) or Static Random Access Memory (SRAM). In some embodiments, when the semiconductor package 2 includes a plurality of semiconductor chips 400, at least one of the plurality of semiconductor chips 400 may be a CPU chip, a GPU chip, or an AP chip, and at least one other chip may be a memory semiconductor chip including a memory device.

The at least one semiconductor chip 400 may include a plurality of chip pads 430 disposed on the active surface. For example, the semiconductor chip 400 may be attached onto the package substrate 100a so that the plurality of chip pads 430 face the package substrate 100a. The plurality of chip terminals 450 may be disposed between the plurality of chip pads 430 and the plurality of upper connection pads 122UP to electrically connect the semiconductor chip 400 to the package substrate 100a. The plurality of chip pads 430 may be electrically connected to the semiconductor device 405.

The semiconductor package 2 may include the molding layer 500a that covers the upper surface of the package substrate 100a and surrounds the semiconductor chip 400 on the package substrate 100a. For example, the molding layer 500a may be a molding member including an EMC. In some embodiments, the molding layer 500a may cover side surfaces and an upper surface of the semiconductor chip 400. In another embodiment, the molding layer 500a may cover the side surfaces of the semiconductor chip 400, but may not cover the upper surface of the semiconductor chip 400. When the molding layer 500a does not cover the upper surface of the semiconductor chip 400, the semiconductor package 2 may further include a heat dissipation member that covers the upper surface of the semiconductor chip 400. The heat dissipation member may include a heat sink such as a heat slug. In addition, the semiconductor package 2 may further include a thermal interface material (TIM) disposed between the heat dissipation member and the semiconductor chip 400. The TIM may include a paste or a film.

In some embodiments, an underfill layer 490 may be disposed between the package substrate 100a and the semiconductor chip 400 to surround the plurality of chip terminals 450 and fill between the package substrate 100a and the semiconductor chip 400. The underfill layer 490 may include resin. For example, the underfill layer 490 may include epoxy resin by using a capillary underfill method. In some embodiments, the underfill layer 490 may be a mixture of filler, and the filler may include, for example, silica. In some embodiments, the semiconductor package 2 may not include the underfill layer 490, and the molding layer 500a may include a molded under fill (MUF) surrounding the plurality of chip terminals 450 and disposed between the package substrate 100a and the semiconductor chip 400.

The electromagnetic shielding layer 900a may integrally cover the side surface of the package substrate 100a and the side surfaces and the upper surface of the molding layer 500a. The electromagnetic shielding layer 900a is generally the same as the electromagnetic shielding layer 900 shown in FIG. 1, and thus, a redundant description thereof may be omitted. The electromagnetic shielding layer 900a may shield electromagnetic waves radiated from the at least one semiconductor chip 400 and electromagnetic waves radiated from the side surfaces of the package substrate 100a. In some embodiments, the electromagnetic shielding layer 900a may completely cover the side surfaces of the package substrate 100a, but may not cover the lower surface thereof. For example, the electromagnetic shielding layer 900a may completely cover side surfaces of the substrate base 110, the upper solder resist layer 132, and the lower solder resist layer 134. For example, the lowermost end of the electromagnetic shielding layer 900a may be located at the same vertical level as the lower (e.g., lowermost) surface of the package substrate 100a. For example, the lowermost end of the solder resist layer 134 and the lowermost end of the electromagnetic shielding layer 900a may be located at the same vertical level at an edge side of (e.g., adjacent to an edge of) the package substrate 100a.

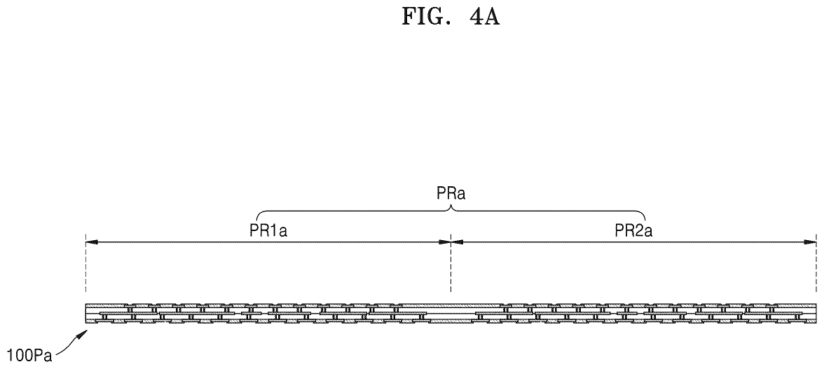

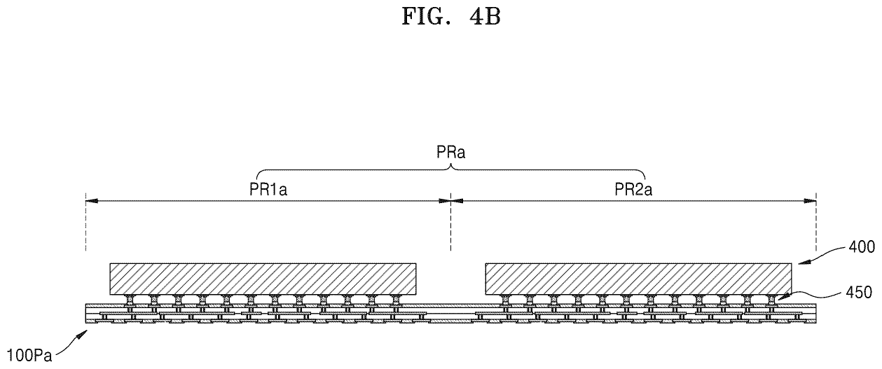

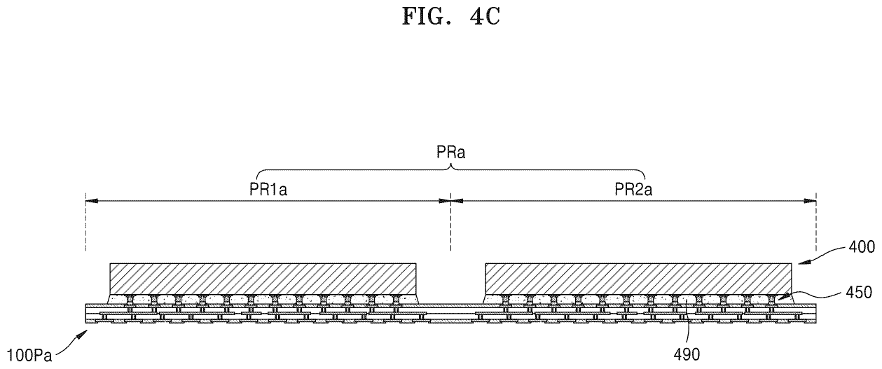

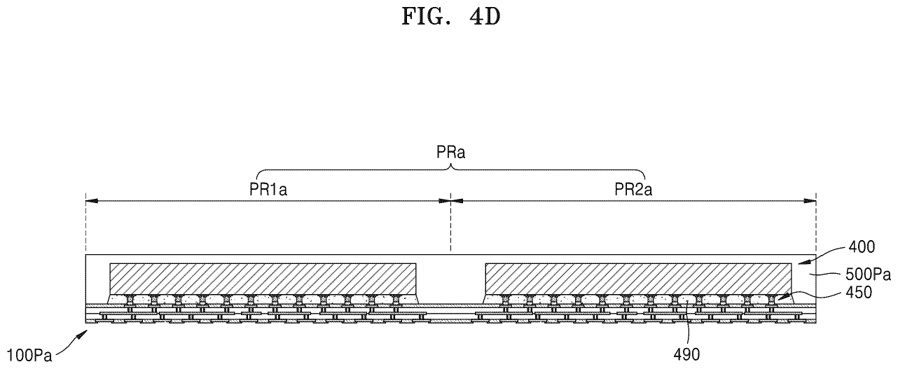

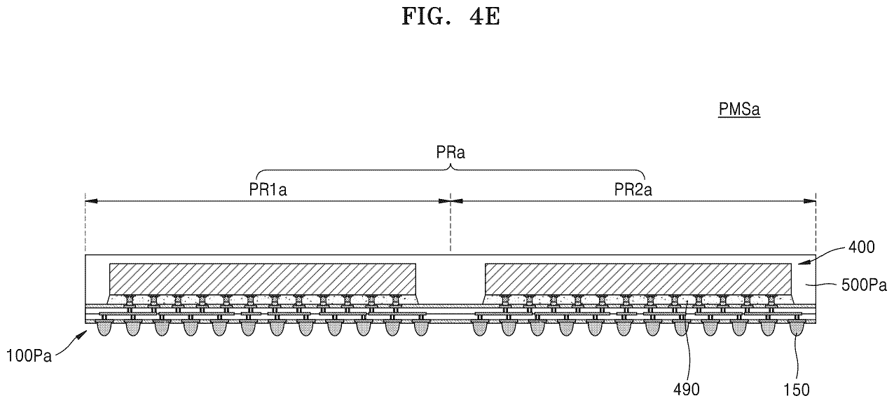

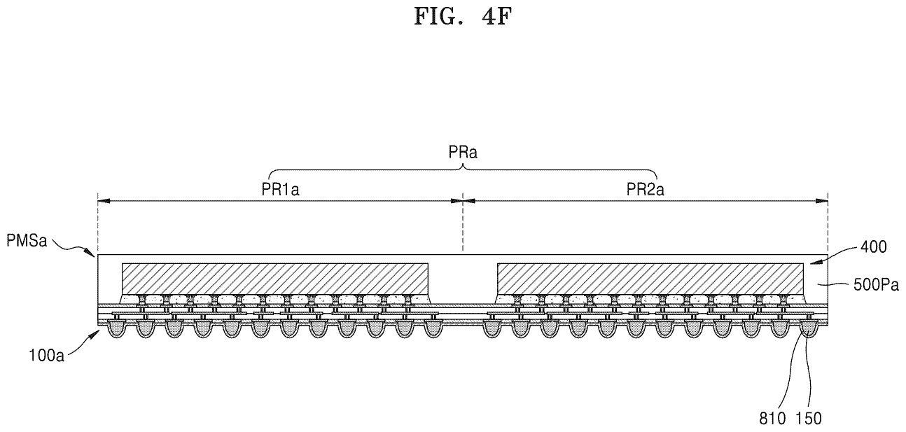

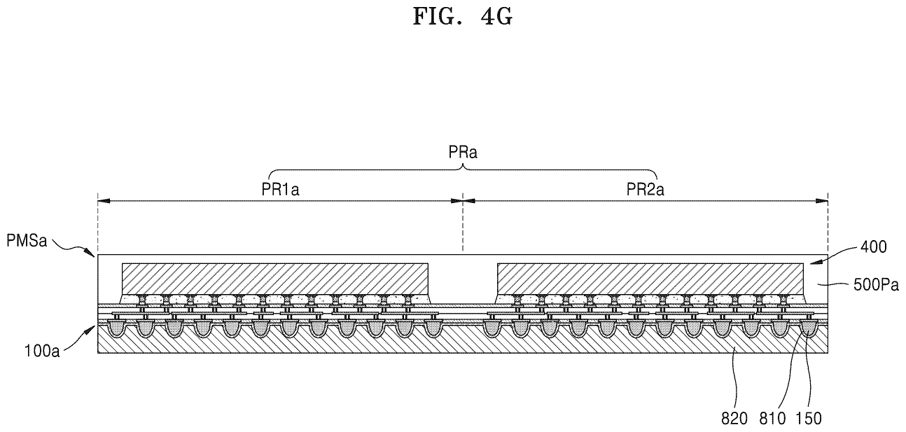

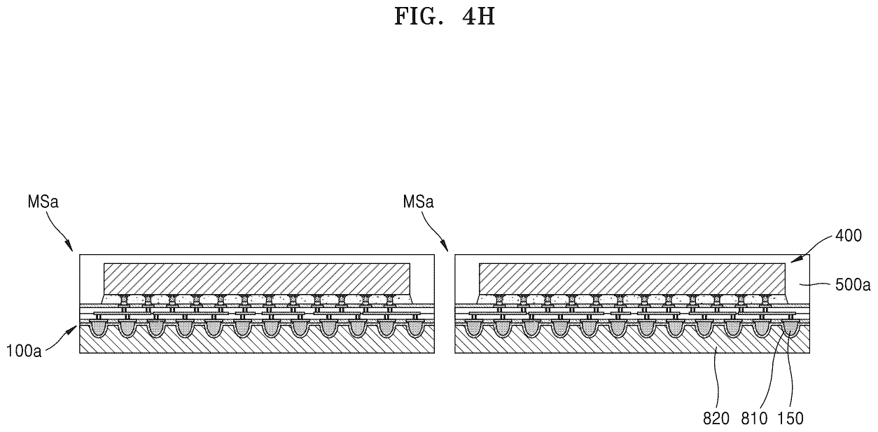

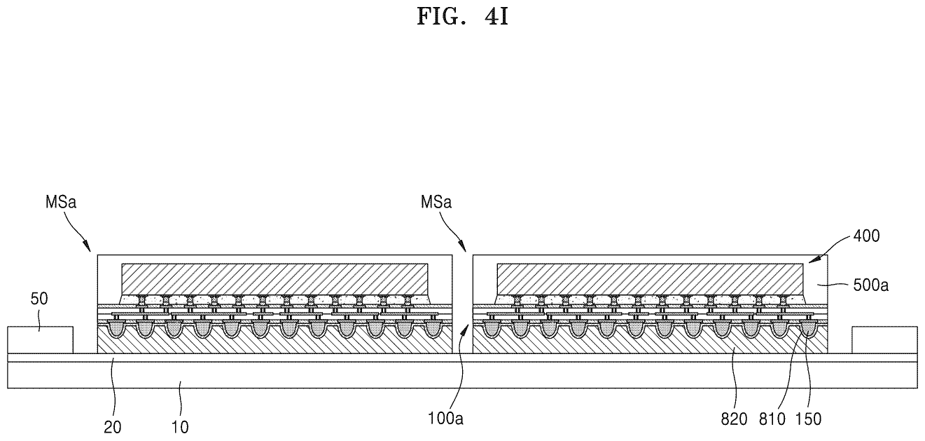

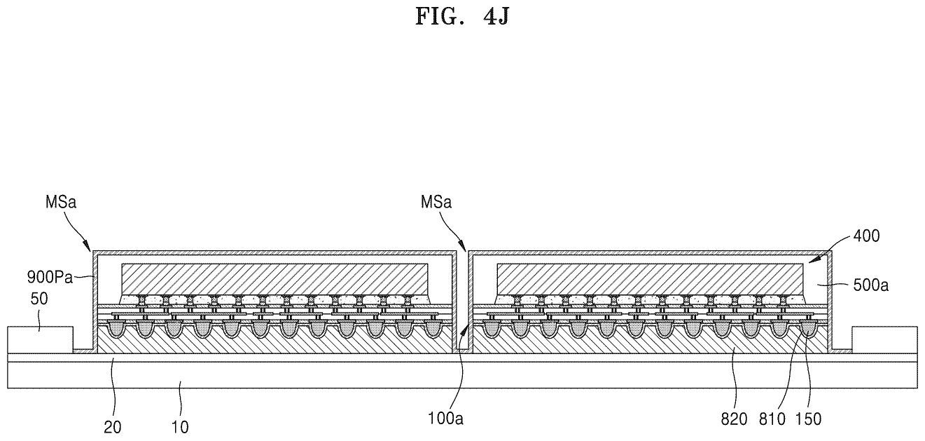

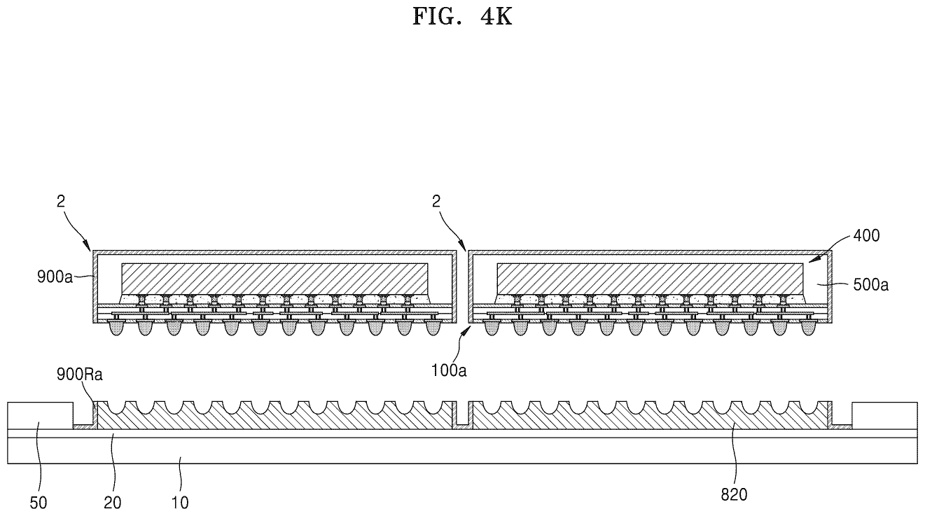

FIGS. 4A to 4K are cross-sectional views showing a method of manufacturing a semiconductor package according to an embodiment. FIGS. 4A to 4K may be described with reference to FIG. 3 together, and redundant descriptions with FIGS. 2A to 2K may be omitted.

Referring to FIG. 4A, a preliminary package substrate 100Pa including a plurality of package regions PRa is prepared. The plurality of package regions PRa includes a first package region PRla and a second package region PR2a. Each of the plurality of package regions PRa of the preliminary package substrate 100Pa, for example, each of the first package region PRla and the second package region PR2a, may correspond to respective regions of the package substrate 100a shown in FIG. 3.

Referring to FIG. 4B, the at least one semiconductor chip 400 is attached to each of the plurality of package regions PRa of the preliminary package substrate 100Pa, for example, each of the first package region PRla and the second package region PR2a. The at least one semiconductor chip 400 may be attached onto the preliminary package substrate 100Pa so that an active surface faces downward, that is, toward the preliminary package substrate 100Pa. The plurality of chip terminals 450 may be disposed between the plurality of chip pads 430 and the plurality of upper connection pads 122UP to electrically connect the semiconductor chip 400 to the preliminary package substrate 100Pa.

Referring to FIG. 4C, the underfill layer 490 is formed between the preliminary package substrate 100Pa and the semiconductor chip 400 to surround the plurality of chip terminals 450 and fill between the preliminary package substrate 100Pa and the semiconductor chip 400. In some embodiments, the underfill layer 490 may not be formed and may be omitted.

Referring to FIG. 4D, a preliminary molding layer 500Pa is formed on the preliminary package substrate 100Pa to cover an upper surface of the preliminary package substrate 100Pa and surround the at least one semiconductor chip 400. The preliminary molding layer 500Pa may include, for example, EMC. In some embodiments, when the underfill layer 490 is disposed between the preliminary package substrate 100Pa and the semiconductor chip 400, the preliminary molding layer 500Pa may be formed to cover the upper surface of the preliminary package substrate 100Pa and surround the underfill layer 490 and the at least one semiconductor chip 400. In some embodiments, when the underfill layer 490 is not disposed between the preliminary package substrate 100Pa and the semiconductor chip 400, the preliminary molding layer 500Pa may be formed as an MUF to cover the upper surface of the preliminary package substrate 100Pa, surround the plurality of surround the chip terminal 450, fill between the package substrate 100a and the semiconductor chip 400, and surround the at least one semiconductor chip 400.

Referring to FIG. 4E, the plurality of package connection terminals 150 are attached to the plurality of lower connection pads 122LP of the preliminary package substrate 100Pa. The preliminary package substrate 100Pa, the at least one semiconductor chip 400, the preliminary molding layer 500Pa, and the plurality of package connection terminals 150 may be collectively referred to as a package molding structure PMSa.

Referring to FIG. 4F, the release layer 810 covering a lower surface of the preliminary package substrate 100Pa and the plurality of package connection terminals 150 is formed. The release layer 810 may be formed to conformally cover the lower surface of the preliminary package substrate 100Pa and to conformally cover surfaces of the plurality of package connection terminals 150. For example, the release layer 810 may conformally cover the plurality of package connection terminals 150 such that protrusions are formed in the release layer 810 corresponding to the positions of the plurality of package connection terminals 150.

Referring to FIG. 4G, the adhesive layer 820 covering the release layer 810 and surrounding the plurality of package connection terminals 150 is formed on the lower surface of the preliminary package substrate 100Pa. The adhesive layer 820 may be formed to have a thickness that may surround the plurality of package connection terminals 150. For example, the adhesive layer 820 may cover the lowermost surfaces of the plurality of package connection terminals 150 and may also horizontally surround the plurality of package connection terminals 150.

Referring to FIGS. 4G and 4H together, the package molding structure PMSa in which the release layer 810 and the adhesive layer 820 are formed is separated such that each of the separated portions corresponds to a respective package region of the plurality of package regions PRa to form a plurality of molding structures MSa. Each molding structure MSa of the plurality of molding structures MSa includes the package substrate 100a, the at least one semiconductor chip 400, the plurality of package connection terminals 150, the release layer 810, and the adhesive layer 820. Each of the plurality of package regions PRa included in the preliminary package substrate 100Pa shown in FIG. 4A may be separated from each other to form package substrates 100a. Each of the plurality of molding structures MSa may include the package substrate 100a corresponding to each of the plurality of package regions PRa, the at least one semiconductor chip 400, and the molding layer 500a disposed on the upper surface of the package substrate 100a, the plurality of package connection terminals 150, the release layer 810, and the adhesive layer 820 which are disposed on the lower surface of the package substrate 100a.

Referring to FIG. 4I, the plurality of molding structures MSa are attached onto the support structure 10 having an upper surface to which the heat resistant tape 20 is attached. In some embodiments, the guide structure 50 surrounding the plurality of molding structures MSa may be attached onto the support structure 10 to which the heat resistant tape 20 is attached.

Referring to FIG. 4J, a preliminary electromagnetic shielding layer 900Pa covering an upper surface and side surfaces of each of the plurality of molding structures MSa is formed. For example, the preliminary electromagnetic shielding layer 900Pa may be formed to cover the side surfaces of each of the release layer 810, the adhesive layer 820, and the package substrate 100a and the side surfaces and the upper surface of the molding layer 500a included in each of the plurality of molding structures MSa.

Referring to FIGS. 4J and 4K, light energy is transmitted to the release layer 810 by laser or UV light to photodecompose the release layer 810 so that the plurality of semiconductor packages 2 each including the package substrate 100a, the at least one semiconductor chip 400, the molding layer 500a, the plurality of package connection terminals 150, and the electromagnetic shielding layer 900a are separated from the adhesive layer 820.

The electromagnetic shielding layer 900a may integrally cover the side surface of the package substrate 100a and the side surfaces and the upper surface of the molding layer 500a. The electromagnetic shielding layer 900a may completely cover the side surfaces of the package substrate 100a, but may not cover the lower surface thereof.

Referring to FIG. 3 and FIGS. 4A to 4K together, the method of manufacturing the semiconductor package 2 according to the inventive concept uses the release layer 810 that is photodecomposed to generate gas and the adhesive layer 820 including a curable polymer. The adhesive layer 820 is formed by applying and curing a glue by using a coating method, and thus, even though sizes of the plurality of package connection terminals 150 increase, the plurality of package connection terminals 150 may be impregnated. In addition, the release layer 810 is photodecomposed and generates gas, thereby easily separating the semiconductor package 2 from the adhesive layer 820, and preventing a burr that protrudes in the shape of a band from being generated in the electromagnetic shielding layer 900a included in the semiconductor package 2 without being clearly cut when separated from the preliminary electromagnetic shielding layer 900Pa.

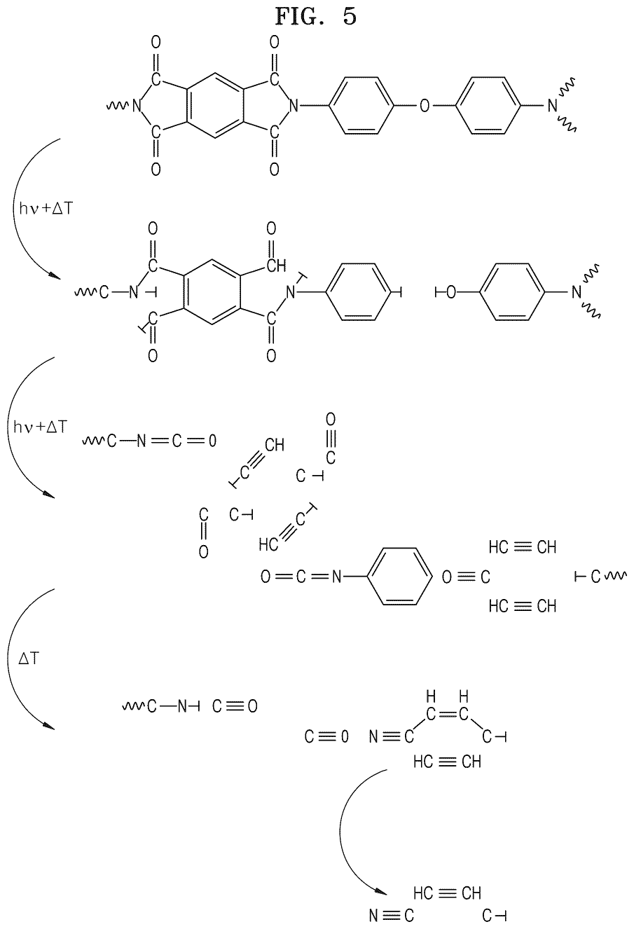

FIG. 5 is a diagram showing the release layer 810 used in a method of manufacturing a semiconductor package according to an embodiment.

Referring to FIG. 5, the release layer 810 shown in FIG. 2F or 4F may include a material that is photodecomposable by light energy and has a heat resistance function. For example, the release layer 810 may include a material that is photodecomposable by a laser. For example, the release layer 810 may include a material that has a heat resistance function at a temperature of about 250° C. or higher. In some embodiments, the release layer 810 may include a material that is photodecomposable by an excimer laser with a wavelength of about 308 nm. For example, the release layer 810 may include polyamic acid (PAA) that is photodecomposable by an excimer laser with a wavelength of about 308 nm.

The PAA may undergo photodecomposition, in which molecules are decomposed by light energy hv of an excimer laser with a wavelength of about 308 nm. In some embodiments, in a process of photodecomposing the PAA, heat energy ΔT may be provided by a process temperature of about 150° C. or higher to promote photodecomposition. The PAA is photodecomposed and may generate gas.

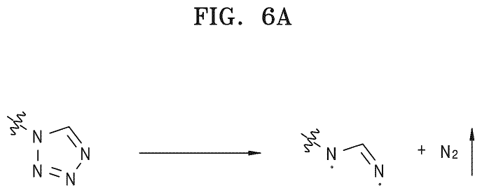

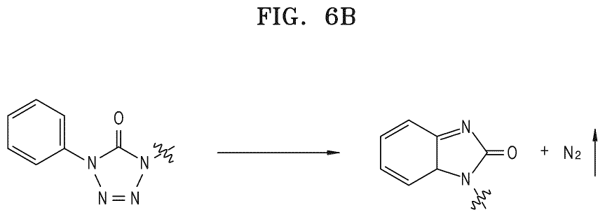

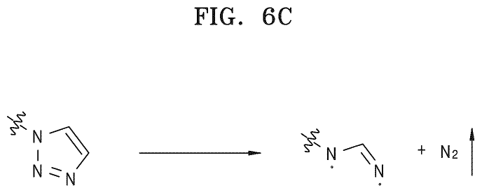

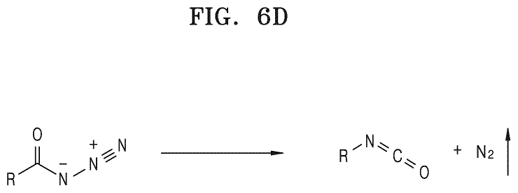

FIGS. 6A to 6D are diagrams showing the release layer 810 used in a method of manufacturing a semiconductor package according to an embodiment.

Referring to FIGS. 6A to 6D together, the release layer 810 shown in FIG. 2F or 4F may include a material that is photodecomposable by light energy and has a heat resistance function. For example, the release layer 810 may include a material that is photodecomposable by UV light. For example, the release layer 810 may include a material that has a heat resistance function at a temperature of about 250° C. or higher. In some embodiments, the release layer 810 may include a material that is photodecomposable by UV light with a wavelength of about 254 nm. For example, the release layer 810 may include tetrazole and derivatives thereof, tetrazolone and derivatives thereof, triazole and derivatives thereof, or acyl azide and derivatives thereof that is photodecomposable by UV light with a wavelength of about 254 nm.

Referring to FIG. 6A, tetrazole and derivatives thereof may be photodecomposed by UV light with a wavelength of about 254 nm. The tetrazole and derivatives thereof may be photodecomposed and generate gas. For example, the tetrazole and derivatives thereof may be photodecomposed and generate nitrogen (N₂) gas.

Referring to FIG. 6B, the tetrazolone and derivatives thereof may be photodecomposed by UV light with a wavelength of about 254 nm. The tetrazolone and derivatives thereof may be photodecomposed and generate gas. For example, the tetrazolone and derivatives thereof may be photodecomposed and generate nitrogen (N₂) gas.

Referring to FIG. 6C, the triazole and derivatives thereof may be photodecomposed by UV light with a wavelength of about 254 nm. The triazole and derivatives thereof may be photodecomposed and generate gas. For example, the triazole and derivatives thereof may be photodecomposed and generate nitrogen (N₂) gas.

Referring to FIG. 6D, the acyl azide and derivatives thereof may be photodecomposed by UV light with a wavelength of about 254 nm. The acyl azide and derivatives thereof may be photodecomposed and generate gas. For example, the acyl azide and derivatives thereof may be photodecomposed and generate nitrogen (N₂) gas.

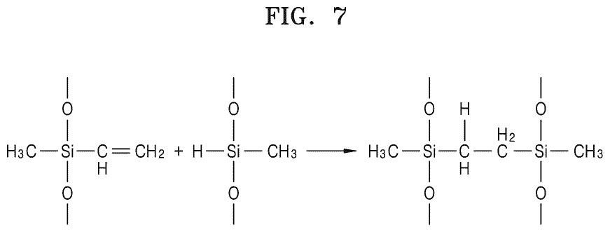

FIG. 7 is a diagram showing the adhesive layer 820 used in a method of manufacturing a semiconductor package according to an embodiment.

Referring to FIG. 7, the adhesive layer 820 shown in FIG. 2G or 4G may include a curable polymer. For example, the adhesive layer 820 may include a thermosetting polymer that may be cured by thermal energy. For example, the adhesive layer 820 may include a polymer that may be thermally cured at a temperature of about 150° C. or higher. In some embodiments, the adhesive layer 820 may include a thermosetting siloxane polymer that may be thermally cured at a temperature of about 150° C. or higher.

The adhesive layer 820 may be formed by applying and curing a glue by using a coating method. The glue applied by using the coating method may include a polymer and an X-linker (cross-linker), and may become a polymer that forms a three-dimensional network when thermally cured. An adhesion force and a modulus of the adhesive layer 820 may be adjusted by adjusting cross-linking density and molecular weight of the polymer. For example, the adhesive layer 820 may be formed to have a modulus of less than about 30 MPa. In some embodiments, the adhesive layer 820 may be formed to have a modulus of about 5 MPa to about 10 MPa.

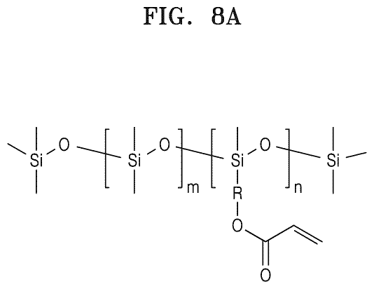

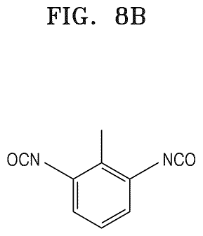

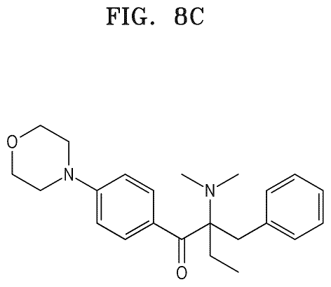

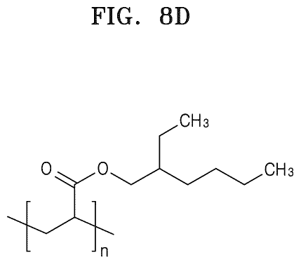

FIGS. 8A to 8D are diagrams showing the adhesive layer 820 used in a method of manufacturing a semiconductor package according to an embodiment.

Referring to FIG. 8A, the adhesive layer 820 shown in FIG. 2G or 4G may include a curable polymer. For example, the adhesive layer 820 may include a thermosetting polymer that may be cured by light energy. For example, the adhesive layer 820 may include a polymer that may be photocured by UV light at about 365 nm. In some embodiments, the adhesive layer 820 may include a heat resistant functional polymer including an acryl binder with a vinyl group substituent that may be photocured by UV light at about 365 nm. For example, the adhesive layer 820 may include a silicone acryl polymer.

The adhesive layer 820 may be formed by applying and photocuring a glue by using a coating method. The glue applied by the coating method may include a silicone acrylate oligomer shown in FIG. 8A, an X-linker shown in FIG. 8B, a photoinitiator shown in FIG. 8C, and a heat resistant binder shown in FIG. 8D. The photoinitiator shown in FIG. 8C may be a UV initiator. The heat resistant binder shown in FIG. 8D may be an acryl binder. The glue may become a polymer that forms a three-dimensional network when photocured. An adhesion force and a modulus of the adhesive layer 820 may be adjusted by adjusting cross-linking density and molecular weight of the polymer. For example, the adhesive layer 820 may be formed to have a modulus of less than about 30 MPa. In some embodiments, the adhesive layer 820 may be formed to have a modulus of about 5 MPa to about 10 MPa.

While the inventive concept has been particularly shown and described with reference to embodiments thereof, it will be understood that various changes in form and details may be made therein without departing from the spirit and scope of the inventive concept.

What is claimed is:

1. A method of manufacturing a semiconductor package, the method comprising:
preparing a plurality of molding structures each comprising:
a package substrate,
at least one semiconductor chip attached onto the package substrate,
a molding layer covering an upper surface of the package substrate and surrounding the at least one semiconductor chip,
a plurality of package connection terminals attached to a lower surface of the package substrate,
a release layer conformally covering the lower surface of the package substrate and conformally covering surfaces of the plurality of package connection terminals, and
an adhesive layer covering the release layer and surrounding the plurality of package connection terminals;
attaching the plurality of molding structures onto a support structure so as to be spaced apart from each other in a horizontal direction;
forming, on the support structure, a preliminary electromagnetic shielding layer covering an upper surface of each of the plurality of molding structures and side surfaces of each of the plurality of molding structures; and
forming a plurality of semiconductor packages by photodecomposing the release layer and separating the adhesive layer from each of the plurality of molding structures, wherein each semiconductor package of the plurality of semiconductor packages comprises:
the corresponding package substrate,
the corresponding at least one semiconductor chip,
the corresponding molding layer,
the corresponding plurality of package connection terminals, and
an electromagnetic shielding layer that is a corresponding separated portion of the preliminary electromagnetic shielding layer that covers the upper surface and side surfaces of the semiconductor package.

2. The method of claim 1, wherein the preparing of the plurality of molding structures includes:
on a preliminary package substrate including a plurality of package regions, attaching the at least one semiconductor chip to each of the plurality of package regions;
forming a preliminary molding layer covering an upper surface of the preliminary package substrate and surrounding the at least one semiconductor chip;
attaching the plurality of package connection terminals to respective regions of the plurality of package regions on a lower surface of the preliminary package substrate;
forming the release layer conformally covering the lower surface of the preliminary package substrate and the surfaces of the plurality of package connection terminals;
forming the adhesive layer covering the release layer and surrounding the plurality of package connection terminals; and
separating the plurality of package regions from each other.

3. The method of claim 2, wherein the forming of the release layer includes covering the lower surface of the preliminary package substrate and the surfaces of the plurality of package connection terminals by using a coating method.

4. The method of claim 2, wherein the adhesive layer includes a thermosetting polymer or a photocurable polymer capable of applying and curing a glue by using a coating method.

5. The method of claim 4, wherein the adhesive layer is formed to have a thickness of a value greater than a height of the plurality of package connection terminals such that the adhesive layer covers lowermost surfaces of the plurality of package connection terminals and horizontally surrounds the plurality of package connection terminals.

6. The method of claim 1, wherein the release layer includes a material that is photodecomposable by laser or ultraviolet (UV) light.

7. The method of claim 6, wherein the release layer includes polyamic acid (PAA) that is photodecomposable by an excimer laser.

8. The method of claim 6, wherein the release layer includes tetrazole and derivatives thereof, tetrazolone and derivatives thereof, triazole and derivatives thereof, or acyl azide and derivatives thereof that are photodegradable by UV light.

9. The method of claim 1, wherein the adhesive layer includes a thermosetting siloxane polymer or a photocurable silicone acryl polymer.

10. The method of claim 1, wherein the forming of the plurality of semiconductor packages includes separating each of the plurality of molding structures from the adhesive layer by gas generated when the release layer is photodecomposed.

11. A method of manufacturing a semiconductor package, the method comprising:
preparing a preliminary package substrate comprising a plurality of package regions;
attaching at least one semiconductor chip onto the preliminary package substrate in each of the plurality of package regions;
forming a preliminary molding layer covering an upper surface of the preliminary package substrate and surrounding the at least one semiconductor chip in each of the plurality of package regions;
forming a package molding structure by attaching a plurality of package connection terminals to a lower surface of the preliminary package substrate in each of the plurality of package regions;
forming a release layer by using a coating method to conformally cover the lower surface of the preliminary package substrate and to conformally cover surfaces of the plurality of package connection terminals;
forming an adhesive layer covering the release layer and surrounding the plurality of package connection terminals;
forming a plurality of molding structures by separating the package molding structure in which the release layer and the adhesive layer are formed such that the separated portions of the package molding structure correspond to each of the plurality of package regions, wherein each of the plurality of molding structures comprises:
a package substrate that is a separated portion of the preliminary package substrate,
the at least one semiconductor chip,
a molding layer that is a separated portion of the preliminary molding layer,
the plurality of package connection terminals,
the release layer, and
the adhesive layer;
attaching the plurality of molding structures to a support structure;
forming a preliminary electromagnetic shielding layer on the support structure to cover an upper surface of each of the plurality of molding structures and side surfaces of each of the plurality of molding structures; and
forming a plurality of semiconductor packages by photodecomposing the release layer and separating the adhesive layer from each of the plurality of molding structures, wherein each semiconductor package of the plurality of semiconductor packages comprises:
the corresponding package substrate,
the corresponding at least one semiconductor chip,
the corresponding molding layer,
the corresponding plurality of package connection terminals, and
an electromagnetic shielding layer that is a corresponding separated portion of the preliminary electromagnetic shielding layer that covers the upper surface and side surfaces of the semiconductor package.

12. The method of claim 11, wherein the forming of the release layer includes forming the release layer with a material that is photodecomposable by light energy from a laser.

13. The method of claim 12, wherein the forming of the plurality of semiconductor packages includes separating each of the plurality of molding structures from the adhesive layer by gas generated when the release layer is photodecomposed by an excimer laser having a wavelength of 308 nm.

14. The method of claim 11, wherein the forming of the release layer includes forming the release layer with a material that is photodecomposable by light energy from ultraviolet (UV) light.

15. The method of claim 14, wherein the forming of the plurality of semiconductor packages includes separating each of the plurality of molding structures from the adhesive layer by nitrogen gas generated when the release layer is photodecomposed by UV light having a wavelength of 254 nm.

16. The method of claim 11, wherein the forming of the adhesive layer includes forming the adhesive layer having a thickness of a value greater than a height of the plurality of package connection terminals and including a thermosetting polymer or a photocurable polymer.

17. The method of claim 11, wherein the forming of the plurality of semiconductor packages includes positioning a lowermost end of the electromagnetic shielding layer at a same vertical level as a lower surface of the package substrate adjacent to an edge of the package substrate.

18. A method of manufacturing a semiconductor package, the method comprising:
preparing a preliminary package substrate comprising a plurality of package regions;
stacking a plurality of semiconductor chips in a step form on the preliminary package substrate in each of the plurality of package regions;
forming a plurality of bonding wires to electrically connect the plurality of semiconductor chips to the preliminary package substrate;
forming a preliminary molding layer covering an upper surface of the preliminary package substrate and surrounding the plurality of semiconductor chips and the plurality of bonding wires in each of the plurality of package regions;
forming a package molding structure by attaching a plurality of package connection terminals to a lower surface of the preliminary package substrate in each of the plurality of package regions;
forming a release layer comprising a material that is photodecomposable by laser or ultraviolet (UV) light by using a coating method to conformally cover the lower surface of the preliminary package substrate and to conformally cover surfaces of the plurality of package connection terminals;
forming an adhesive layer to surround the plurality of package connection terminals, the adhesive layer covering the release layer, the adhesive layer having a thickness of a value greater than a height of the plurality of package connection terminals, and the adhesive layer comprising a thermosetting polymer or a photocurable polymer;
forming a plurality of molding structures by separating the package molding structure in which the release layer and the adhesive layer are formed such that the separated portions of the package molding structure correspond to each of the plurality of package regions, wherein each of the plurality of molding structures comprises:
a package substrate that is a separated portion of the preliminary package substrate,
the plurality of semiconductor chips,
a molding layer that is a separated portion of the preliminary molding layer,
the plurality of package connection terminals,
the release layer, and
the adhesive layer;
attaching the plurality of molding structures onto a support structure;
forming a preliminary electromagnetic shielding layer on the support structure to cover an upper surface of each of the plurality of molding structures and side surfaces of each of the plurality of molding structures; and
forming a plurality of semiconductor packages by photodecomposing the release layer and separating the adhesive layer from each of the plurality of molding structures, wherein each semiconductor package of the plurality of semiconductor packages comprises:
the corresponding package substrate,
the corresponding plurality of semiconductor chips,
the corresponding molding layer,
the corresponding plurality of package connection terminals, and
an electromagnetic shielding layer that is a corresponding separated portion of the preliminary electromagnetic shielding layer that covers the upper surface and side surfaces of the semiconductor package.

19. The method of claim 18, wherein the release layer is formed to have a thickness of about 3 μm to about 10 μm.

20. The method of claim 18, wherein a height of each of the plurality of package connection terminals and a horizontal width of each of the plurality of package connection terminals is about 180 μm to about 350 μm.
